(19) United States
(12) Patent Application Publication
(10) Pub. No.: US 2002/0081501 A1
(43) Pub. Date: Jun. 27, 2002

(54) Device manufacturing method, photomask used for the method, and photomask manufacturing method

(75) Inventors: Norio Hasegawa, Hinodemachi (JP); Toshihiko Tanaka, Tokyo (JP); Tsuneo Terasawa, Ome (JP)

Correspondence Address: Miles & Stockbridge P.C., Suite 500, 1751 Pinnacle Drive, McLean, VA, 22102-3833, US

(73) Assignee: Hitachi, Ltd.

(21) Appl. No.: 10/023,893

(22) Filed: Dec. 21, 2001

(30) Foreign Application Priority Data
Dec. 25, 2000 (JP) 2000-393232

(51) Int. Cl. G03F 9/00

(52) U.S. Cl. 430/5

(57) ABSTRACT

In the case of a resist mask using a resist as an opaque material, problems occur that a foreign matter is produced due to contact with other equipment and becomes a defect for pattern transfer and the yield of manufactured devices is deteriorated. A device is manufactured by using a photomask provided with a resist pattern to which a resist is not attached for a mechanical contact point with other equipment.

### TECHNICAL FIELD OF THE INVENTION

The present invention relates to a photomask and its manufacturing method, particularly to a photomask and its manufacturing method preferred for a device having a micro pattern of a semiconductor integrated circuit device or the like.

### BACKGROUND OF THE INVENTION

To manufacture a semiconductor integrated circuit device, the lithography technology is used as a method for transferring a micro pattern onto a semiconductor wafer. The lithography technology mainly uses a projection aligner. A device pattern is formed by transferring the pattern of a photomask set to the projection aligner onto a semiconductor wafer.

A normal photomask is manufactured by processing an opaque material such as chromium (Cr) formed on a transparent plate such as a quartz substrate. That is, a normal photomask is constituted by forming an opaque film made of chromium into a desired shape on a transparent plate. An opaque film is processed as described below. An electron beam sensitive resist is applied onto an opaque film and then, a desired pattern is written on the electron beam sensitive resist by an electron beam writing apparatus. Then, a resist pattern of a desired shape is formed through development and then an opaque film is processed through dry etching or wet etching by using the resist pattern as a mask. Then, the resist is removed and then the opaque film is cleaned to form an opaque pattern of a desired shape on the transparent plate.

Because LSI development competition has advanced and it has been necessary to accelerate device debugging, many photomasks have been necessary and the necessity for manufacturing photomasks at a low cost has been raised. Moreover, the necessity for manufacturing photomasks in a short manufacturing period (TAT) has been also raised. Particularly, because the demand for small quantities and various types of system LSIs has been raised, the request has been enhanced.

To simplify a photomask manufacturing process and decrease the cost, official gazettes of Japanese Patent Application Laid-Open Nos. 5-289307 and 9-211837 disclose the so-called resist mask method for forming an opaque film by a resist film. According to this method, processes for etching an opaque film and removing a resist are unnecessary and it is possible to shorten the TAT by reduction of photomask cost and simplification of photomask processes.

### SUMMARY OF THE INVENTION

Though Cr has been used so far as an opaque material, a foreign matter has not easily produced due to contact because Cr is formed on a contact point and because it is a hard metallic portion, so that the problem that the yield of manufactured devices is lowered has hardly occurred. Therefore, when a field portion uses a dark field mask serving as an opaque portion, though a part of Cr formed on the outer periphery is generally contacted, the problem that the yield of devices is lowered due to the contact hardly occurs. However, in the case of a resist mask using a resist which is a sensitive composition as an opaque material, problems occurs that the resist serving as an opaque material is removed due to contact, a foreign matter is produced to function as a defect of pattern transfer, and yields of manufactured devices and masks are lowered. However, these problems have not been considered so far. For example, the above problems and their solving means are not disclosed in the official gazette of Japanese Patent Application Laid-Open No. 5-289307 or 9-211837.

As described above, to solve the problems when using a photomask with a resist, the present invention provides a photomask with a resist having a structure in which the resist is not attached to a contact point with other system or the like.

Moreover, the present invention provides a method for manufacturing a device or a photomask by using a photomask with a resist having a structure in which the resist is not attached to a contact point with other system or the like.

Other problems and novel features of the present invention will become more apparent by using the following embodiments of the present invention and accompanying drawings.

### BRIEF DESCRIPTION OF THE DRAWINGS

FIG. 1A is a plan view of a photomask of a first embodiment of the present invention used to manufacture a semiconductor integrated circuit device,

FIG. 1B is a sectional view taken along the line A-A in FIG. 1A, and

FIG. 1C is a sectional view of an essential portion of the photomask in FIGS. 1A and 1B when setting the photomask to a predetermined equipment;

FIGS. 2A to 2C are sectional views of essential portions in the manufacturing process of the optical mask in FIGS. 1A to 1C, namely,

FIG. 2A shows a transparent plate formed with a synthetic quarts substrate,

FIG. 2B shows a resist film 1R having a property for absorbing a vacuum ultraviolet beam applied on the entire principal plane of the transparent plate, and

FIG. 2C shows an opaque pattern and a mark pattern respectively formed with a resist film.

FIG. 3 is a graph showing spectral transparencies of typical electron beam resist films;

FIG. 4 is a sectional view of an essential portion of a semiconductor wafer schematically showing a photoresist pattern transferred onto a semiconductor wafer by using the optical mask in FIGS. 1A to 1C;

FIG. 5 is an illustration of a reduction projection aligner;

FIG. 6 is a sectional view of an essential portion of a semiconductor wafer in the manufacturing process of a semiconductor integrated circuit device;

FIG. 7 is a sectional view of an essential portion of a the semiconductor wafer in the manufacturing process of the semiconductor integrated circuit device continued from FIG. 6;

FIG. 8 is a sectional view of an essential portion of the semiconductor wafer in the manufacturing process of the semiconductor integrated circuit device continued from 7;

FIG. 9 is a sectional view of an essential portion of the semiconductor wafer in the manufacturing process of the semiconductor integrated circuit device continued from 8;

FIG. 10 is a flowchart showing a mask manufacturing process;

FIGS. 11A and 11B are illustrations showing a mask set to an electron beam writing apparatus, in which

FIG. 11A is a plan view of the mask set to an electron beam writing apparatus and

FIG. 11B is a sectional view of the mask set to an electron beam writing apparatus;

FIG. 12A is an illustration showing a method for preventing a photomask from being electrified and 12B is also an illustration showing a method for preventing a photomask from being electrified;

FIGS. 13A and 13B are structural illustrations of a photomask, in which

FIG. 13A is a plan view of the photomask and

FIG. 13B is a sectional view of the photomask;

FIGS. 14A and 14B are illustrations for explaining a mask handing method, namely,

FIG. 14A shows a resist applied to a photomask plate and

FIG. 14B shows a portion 14-6 in FIG. 14A viewed from A;

FIGS. 15A and 15B are illustrations for explaining a resist forming method, namely,

FIG. 15A shows a method for applying a resist to the surface of a mask and

FIG. 15B shows an outline of application of resist to the surface of a mask;

FIG. 16 is a structural illustration showing a structure of a mask;

FIG. 17 is a plan view of a photomask used for a manufacturing method of a semiconductor integrated circuit device of an embodiment of the present invention;

FIG. 18 is a plan view of a photomask used for a manufacturing method of a semiconductor integrated circuit device of an embodiment of the present invention;

FIG. 19 is a plan view of an essential portion of a photomask used for a manufacturing method of a semiconductor integrated circuit device of an embodiment of the present invention;

FIG. 20 is a plan view of an essential portion of a photomask used for a manufacturing method of a semiconductor integrated circuit device of an embodiment of the present invention;

FIG. 21 is an illustration showing a flow of the pattern data processing of an optical mask used for an embodiment of the present invention and a schematic configuration of an equipment performing the processing;

FIG. 22 is an illustration showing a flow of a manufacturing process of an optical mask used for an embodiment of the present invention;

FIG. 23 is a plan view of an optical mask used for an embodiment of the present invention, showing an area from which a resist film should be removed;

FIG. 24A is a plan view of an optical mask used for a manufacturing method of a semiconductor integrated circuit device of an embodiment of the present invention and 24B is a sectional view taken along the line TA-TA′ in FIG. 24A;

FIG. 25 is an illustration showing a state of setting an optical mask to a mask inspection apparatus;

FIG. 26 is an illustration showing a state of setting an optical mask to another mask inspection apparatus;

FIG. 27A is a plan view showing a state of housing an optical mask used for an embodiment of the present invention in a stock case and

FIG. 27B is a sectional view taken along the line TA-TA′ in FIG. 27A;

FIG. 28 is an illustration showing a state of handling an optical mask;

FIG. 29 is a plan view of an optical mask used for another embodiment of the present invention, which is an illustration showing an area from which a resist film should be removed;

FIG. 30 is an illustration showing a flow of the pattern data processing of an optical mask used for another embodiment of the present invention;

FIG. 31 is an illustration showing a schematic configuration of a reduction projection aligner;

FIG. 32 is a sectional view of an essential portion of a photomask of an embodiment of the present invention set to a predetermined equipment;

FIG. 33 is a sectional view of an essential portion of a photomask of an embodiment of the present invention set to a predetermined equipment;

FIG. 34 is a sectional view of an essential portion of a photomask of an embodiment of the present invention set to a predetermined equipment; and

FIG. 35 is a system block diagram of management or usage of the data for a contact area with a manufacturing system in a photomask of an embodiment of the present invention.

### DETAILED DESCRIPTION OF THE PREFERRED EMBODIMENTS

Embodiments of the present invention are described below by referring to the accompanying drawings. Manufacturing of a semiconductor integrated circuit, a photomask used for the circuit, and a manufacturing method of the photomask are mainly described below. However, the technical thought of the present invention is not restricted to the above mentioned. The present invention can be also applied to manufacturing methods of a superconducting device, an optical element device, a micromachine, a microdevice, a photomask, a TFT, a wiring board, a DNA chip, and a biosensor, and a photomask used for the manufacturing method, and a manufacturing method of the photomask. Moreover, the term “semiconductor integrated circuit device” includes not only a device formed on a semiconductor or an insulating substrate such as a silicon wafer or a sapphire substrate but also a device formed on other insulating substrate of glass such as a TFT (Thin Film Transistor) and a TN (Super Twisted Nematic) liquid crystals. Moreover, an opaque film or an opaque pattern formed with a resist includes an opaque body having a function for shifting a phase, the so-called halftone phase shifter.

In the case of the embodiments, a p-channel MISFET (Metal Insulator Semiconductor Field Effect Transistor) is abbreviated to as a pMIS and an n-channel MISFET is abbreviated as an nMIS.

(First Embodiment)

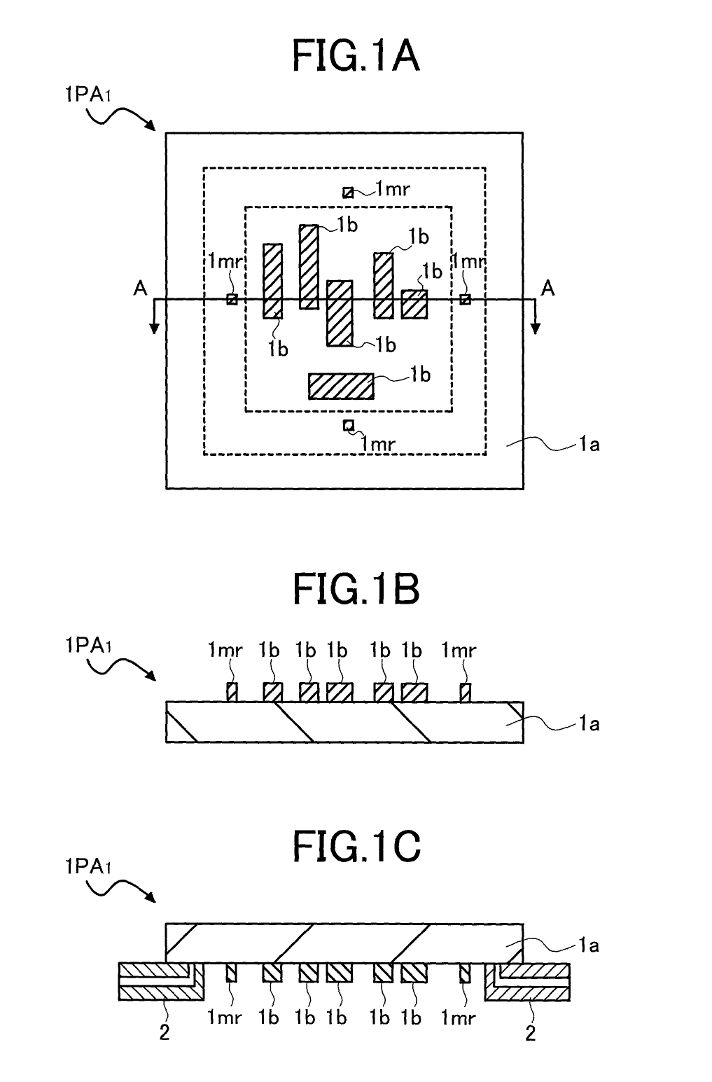

FIG. 1A is a plan view of a photomask of a first embodiment of the present invention used to manufacture a semiconductor integrated circuit device, FIG. 1B is a sectional view taken along the line A-A in FIG. 1A, and FIG. 1C is sectional view of a photomask showing a state when mounting the photomask in FIGS. 1A and 1B on a predetermined device. Broken lines in FIG. 1A are illustrated so that description is easily understood but they do not show real dimensions.

The photomask 1PA1 of this first embodiment is a photomask for imaging and transferring the original drawing of a semiconductor integrated circuit pattern having, for example, dimensions 5 times larger than actual dimensions on a semiconductor wafer through a reduction projection optical system or the like, which is used for a projection exposure apparatus using g-beam (wavelength of 436 nm), i-beam (wavelength of 365 nm), krypton-fluoride (KrF) excimer laser beam (wavelength of 248 nm), argon-fluoride (ArF) excimer laser beam (wavelength of 193 nm), or fluorine-gas (F₂) laser beam (wavelength of 157 nm) as a light source. It is a matter of course that a photomask of the present invention can be used not only for a reduction projection exposure apparatus but also for a 1:1 exposure apparatus.

A transparent plate 1a constituting the photomask 1PA1 is made of, for example, quadrangular transparent synthetic quartz glass. The area enclosed by the innermost broken line in FIG. 1A shows an integrated circuit pattern area serving as an area in which an integrated circuit pattern to be transferred is set. An opaque pattern 1b for transferring an integrated circuit pattern on a semiconductor wafer is set in the integrated circuit pattern area. In the case of the first embodiment, the opaque pattern 1b is formed with a resist film. In this case, a resist denotes a sensitive composition and includes not only a general electron beam resist and photoresist using alicyclic compounds such as novolac resin, phenol resin, and norbornene, and an electron beam resist and photoresist using acrylic resin but also a material sensitive to an electron beam, ultraviolet radiation, and far ultraviolet radiation and on which a pattern can be formed through development. Moreover, the resist includes a sensitive composition containing black carbon and a sensitive composition containing scattered fine particles of metal oxide (e.g. Ti oxide). Furthermore, the resist includes the so-called non-chemical amplification resist in which a photosensitive agent such as naphthoquinone diazide directly reacts to exposure light (electron), a chemical amplification resist from which photosensitivity is obtained by an acid catalyst reaction, and a chemical multiplication resist in which a chemical multiplication reaction progresses like a cascade. Furthermore, the resist includes a resist inferior in etching resistance.

The outside of the above integrated circuit pattern area is an integrated circuit pattern circumferential area which is an area other than the integrated circuit pattern area. An area enclosed by a broken line outside of the integrated circuit pattern area is an area corresponding to an circumferential internal area which is an inside area in which an optical pattern is formed in the circumferential area which is an external area not covered with a pellicle, in which a mark pattern 1mr for detecting the information for the photomask 1PA1 is formed. In the case of this first embodiment, the mark pattern 1mr is also formed with a resist film. The mark pattern 1mr includes an alignment mark and a calibration mark used to manufacture a photomask. The alignment mark is a mark used to align the photomask 1PA1 with a photomask manufacturing system or a device manufacturing system by detecting the position of the photomask 1PA1 when setting the photomask 1PA1 to the photomask or device manufacturing system. The above photomask manufacturing system includes a photomask exposure apparatus (e.g. pattern exposure apparatus), a photomask pattern writing apparatus, a resist application apparatus, a resist development apparatus, a photomask dimension measurement apparatus, a photomask inspection apparatus, a photomask adjustment apparatus, and a photomask installation apparatus. The device manufacturing system (e.g. semiconductor manufacturing system) also includes an exposure apparatus and an installation apparatus. Moreover, the calibration mark is a mark used to measure pattern misalignment, pattern shape state, or pattern transfer accuracy. The mark patter 1mr is a pattern that is not transferred onto a semiconductor wafer.

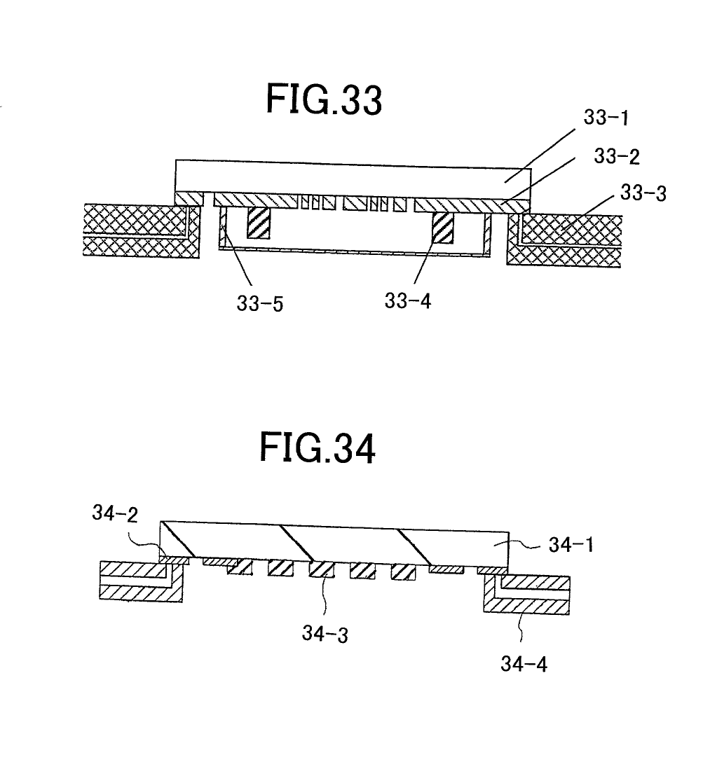

Moreover, the outside of the circumferential internal area is a circumferential external area (circumferential area serving as a portion used for vacuum adsorption) for the photomask 1PA1 to directly contact with the holder 2 of a photomask manufacturing system or device manufacturing system (e.g. pattern exposure apparatus) when the photomask 1PA1 is set to the holder 2 of the photomask manufacturing system or a device manufacturing system as shown in FIG. 1C. In the case of this first embodiment, a pattern forming resist film is not formed in the circumferential external area. When the resist film is formed in the circumferential external area, a foreign matter is produced if the resist film is removed or chipped when setting the photomask 1PA1 to a photomask manufacturing system or a device manufacturing system. In the case of this first embodiment, however, it is possible to prevent a trouble of removal of a resist film or occurrence of a foreign matter due to the above mechanical impact because a resist film is not formed in the circumferential external area. Moreover, the holder 2 having a vacuum adsorption mechanism is illustrated in FIG. 1C. FIG. 1C shows the holder of an exposure apparatus. However, also when an operator directly holds and handles a photomask in the photomask manufacturing step, dimension measuring step, inspecting step, adjusting step, pellicle-frame setting step, and carrying step, handles the photomask with a photomask jig, and houses the photomask in a photomask vessel, it is necessary to use a structure in which a resist is not present in an area where the resist may be damaged. Moreover, it is allowed that a photomask having the above structure is provided with an opening 32-3 for shifting a phase so as to be different from the phase of the light passing through a not-etched portion by approx. 180° by etching a transparent plate 32-1 as shown in FIG. 32 or provided with a phase shifter 33-2 made of a halftone material or quartz, for example, in addition to a transparent plate 33-1 and a resist pattern 33-4 as shown in FIG. 33. It is preferable to use a halftone material capable of serving as a halftone shifter in which a halftone film also serving as a phase shifter and an opaque film has a transparency of 1% or more and less than 40% and a phase-shift value when compared with that of a portion free from the halftone film inverts a light phase. Moreover, as shown in FIG. 34, there is a method of forming the mechanical contact point of a mask stage 34-4 or the like by a metal 34-2.

Then, a method for manufacturing the photomask 1PA1 in FIG. 1 is described below.

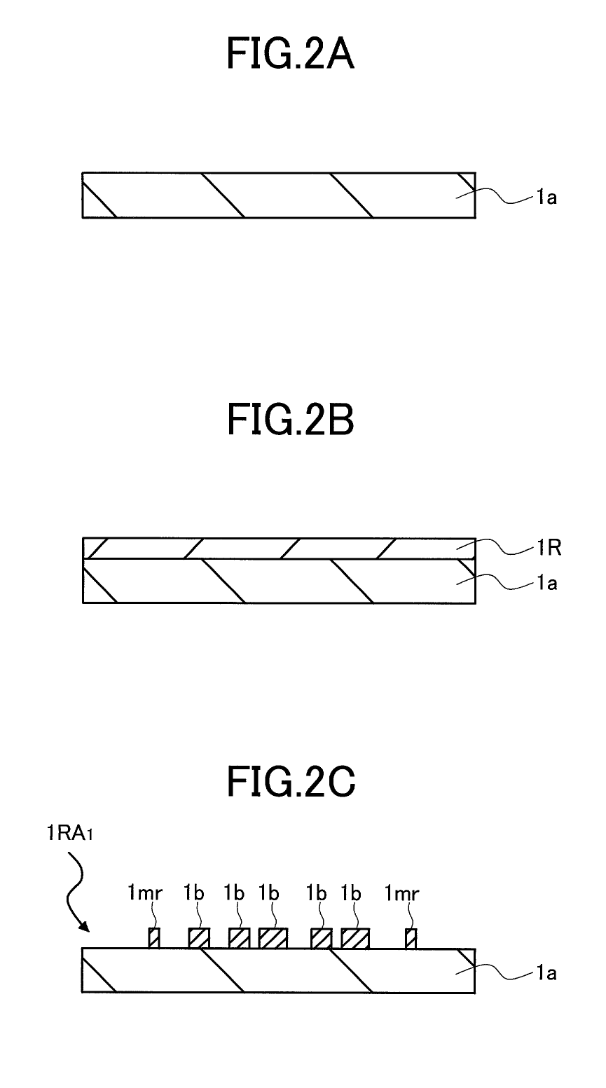

First, a transparent plate 1a formed with a synthetic quarts substrate having a thickness of approx. 6 mm is prepared as shown in FIG. 2A and then, a resist film 1R having a property for absorbing a vacuum ultraviolet beam such as an ArF excimer laser beam or F₂ laser beam is applied on the entire principal plane of the transparent plate 1a by spin coating or the like as shown in FIG. 2B. The resist film 1R is a resist film reactive to an electron beam. In this case, a novolac-based resist film is formed at a thickness of 150 nm, for example.

Then, as shown in FIG. 2C, an opaque pattern 1b and a mark pattern 1mr respectively formed with a resist film are formed by a method same as the method for forming a desired pattern in the normal photomask manufacturing process. In this case, an action is taken for electrification of an electron beam to be described later. Moreover, because the circumferential portion of the photomask 1PA1 serves as a contact point with, for example, a projection exposure apparatus, the resist film is removed to prevent a foreign matter from being produced due to removal or chips of the resist film caused by a mechanical impact.

The resist film 1R uses, for example, a copolymer of poly(α-methylstyrene-co-α-chloroacrylic acid), a material mainly containing novolac resin and quinone diazide, novolac resin and poly(methyl-1-pentene sulfone, or chloromethylated polystyrene. It is possible to use the so-called chemical-amplification resist obtained by adding an inhibitor and an acid-producing agent to phenol resin or novolac resin. It is necessary that the material of the resist film 1R has an shading characteristic to the light source of a projection exposure apparatus and a characteristic having a sensitivity to the light source of a pattern writing apparatus such as an electron beam in the photomask manufacturing process. However, the material is not restricted to the above materials but it can be variously changed. Moreover, the thickness of the film 1R is not restricted to 150 nm but any thickness is allowed as long as the thickness meets the above conditions.

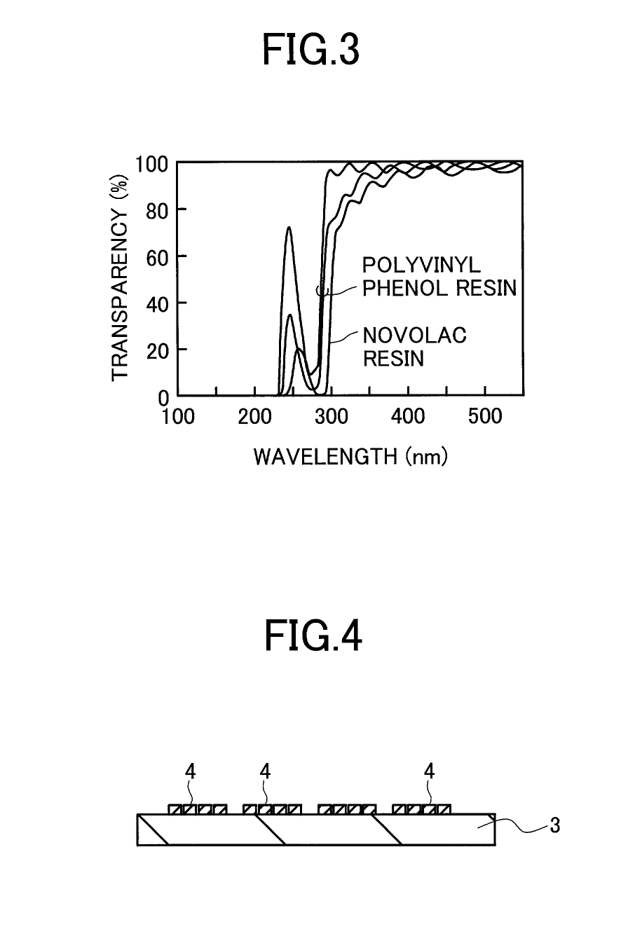

FIG. 3 shows the spectral transparency of a typical electron beam resist film. When forming polyphenol resin and novolac resin into films at a thickness of approx. 100 nm, they have a transparency of approx. 0 at a wavelength of 150 to 230 nm, for example, and have a sufficient masking effect for an ArF excimer laser beam having a wavelength of 193 nm, for example, and a F₂ laser beam having a wavelength of 157 nm. In this case, vacuum ultraviolet radiation having a wavelength of 200 nm or less is used but a laser beam is not restricted to the vacuum ultraviolet radiation. It is necessary to use another masking material or add an absorbent to a resist film for an KrF excimer laser beam having a wavelength of 248 nm. Moreover, it is effective to perform the so-called resist-film hardening treatment of adding a heat treatment step or previously strongly applying ultraviolet radiation in order to improve the resistance against exposure light irradiation after forming the opaque pattern 1b or mark pattern 1mr formed with a resist film. Moreover, it is effective to keep a pattern face in the atmosphere of inert gas such as nitrogen (N₂) or the like in order to prevent a resist film from being oxidized. Not only electron beam writing but also pattern writing by ultraviolet radiation of 230 nm or more, for example, writing by a laser, and pattern exposure can be applied to pattern writing of a resist film. The gist of the present invention lies in the fact of using a resist film as a photomask and providing a practical photomask structure. Therefore, it is allowed to use any other shading wavelength, resist material, and transparent plate material.

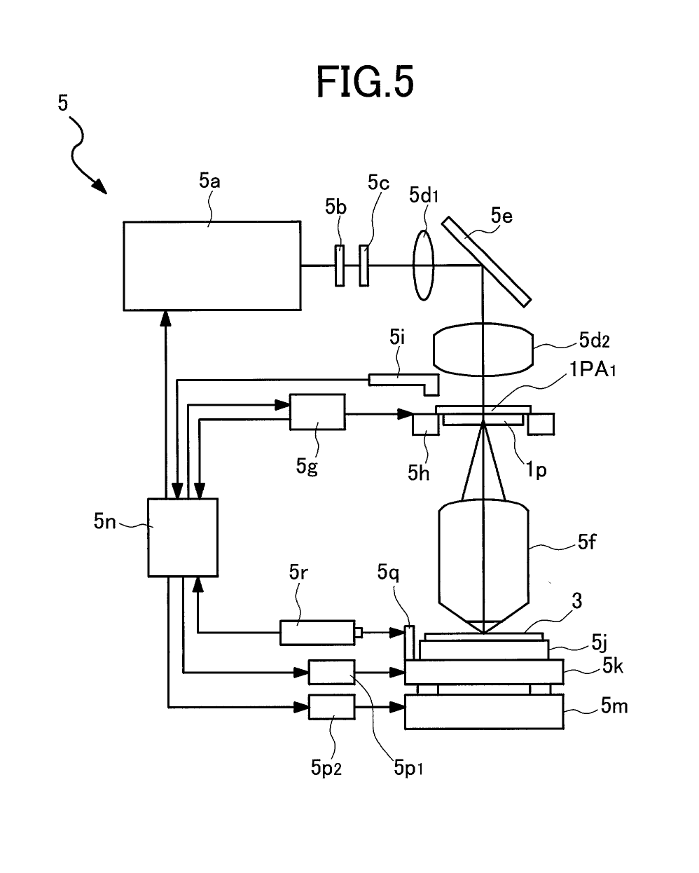

A pattern is transferred by a reduction projection aligner by using the above photomask 1PA1. The projection light of the reduction projection aligner uses an ArF excimer laser beam having a wavelength of approx. 193 nm, for example, and the numerical aperture NA of a projection lens uses approx. 0.68 and the coherency σ of a light source uses, for example, 0.7. A normal positive resist film having a photosensitivity to ArF is formed on a semiconductor wafer serving as a workpiece at a thickness of approx. 300 nm. The reduction projection aligner is aligned with the photomask 1PA1 by detecting the mark pattern 1mr formed on the photomask 1PA1. A helium-neon (He—Ne) laser beam having, for example, a wavelength of 633 nm is used for the above alignment. Therefore, the mask pattern 1mr constituted by a resist film does not have the shading effect and the contrast between the light passing through the mark pattern 1mr and the light passing through a transparent portion cannot be obtained. Therefore, the scattered light at the edge of the mark pattern 1mr is detected. Thereby, as shown in FIG. 4, the semiconductor integrated circuit pattern on the photomask 1PA1 is projected onto the principal plane (first principal plane) of a semiconductor wafer 3 by the normal method to form a resist pattern 4 through the normal heat treatment and development steps. As a result, a pattern transfer characteristic is obtained which is almost the same as the case of using a photomask obtained by forming a metallic film made of chromium (Cr) or the like on a transparent plate as an opaque pattern. For example, a 0.19-μm line-and-space can be formed at a focal depth of 0.4 μm.

FIG. 5 shows a reduction projection aligner used for the above exposure treatment. The exposure light emitted from the light source 5a of the reduction projection aligner 5 irradiates the photomask 1PA1 through a fly eye lens 5b, an illumination-pattern control aperture 5c, condenser lenses 5d1 and 5d2, and a mirror 5e. The photomask 1PA1 is mounted while turning the principal plane (first principal plane) on which an opaque pattern is formed downward (semiconductor waver-3 side). Therefore, the above exposure light is irradiated from the back (second principal plane) of the photomask 1PA1. Thereby, a mask pattern written on the photomask 1PA1 is projected onto the semiconductor wafer 3 serving as a workpiece through a projection lens 5f. A pellicle 1p for preventing a pattern from being ill-transferred due to attachment of a foreign matter may be formed on the first principal plane of the photomask 1PA1 according to necessity. The photomask 1PA1 is vacuum-attracted onto a mask stage 5h controlled by mask-position controller 5g, aligned by a position monitor tool 5i, and therefore the center of the photomask 1PA1 is accurately aligned with the optical axis of the projection lens 5f. The semiconductor wafer 3 is vacuum-attracted onto a sample stage 5j. The sample stage 5j is mounted on a Z stage 5k movable in the optical-axis direction of the projection lens 5f, that is, Z-axis direction and moreover mounted on an XY stage 5m. Because the Z stage 5k and XY stage 5m are driven by drivers 5p1 and 5p2 in accordance with a control command output from a main controller 5n, each of the stages 5k and 5m can move to a desired exposure position. The position is accurately monitored by a laser measuring system 5r as the position of a mirror 5q fixed to the Z stage 5k. Moreover, the position monitor tool 5i uses a halogen lamp, for example. That is, it is preferable that a conventional reduction projection aligner can be used without using a special light source for the position monitor tool 5i (without introducing a new art or newly introducing a difficult art). However, it is also allowed to newly use a position monitor tool having a special light source. The fact that new position monitor tool is not used is effective in suppressing the increase of the cost of a product manufactured by using the photomask 1PA1 for forming an opaque pattern by a resist film on the photomask 1PA1.

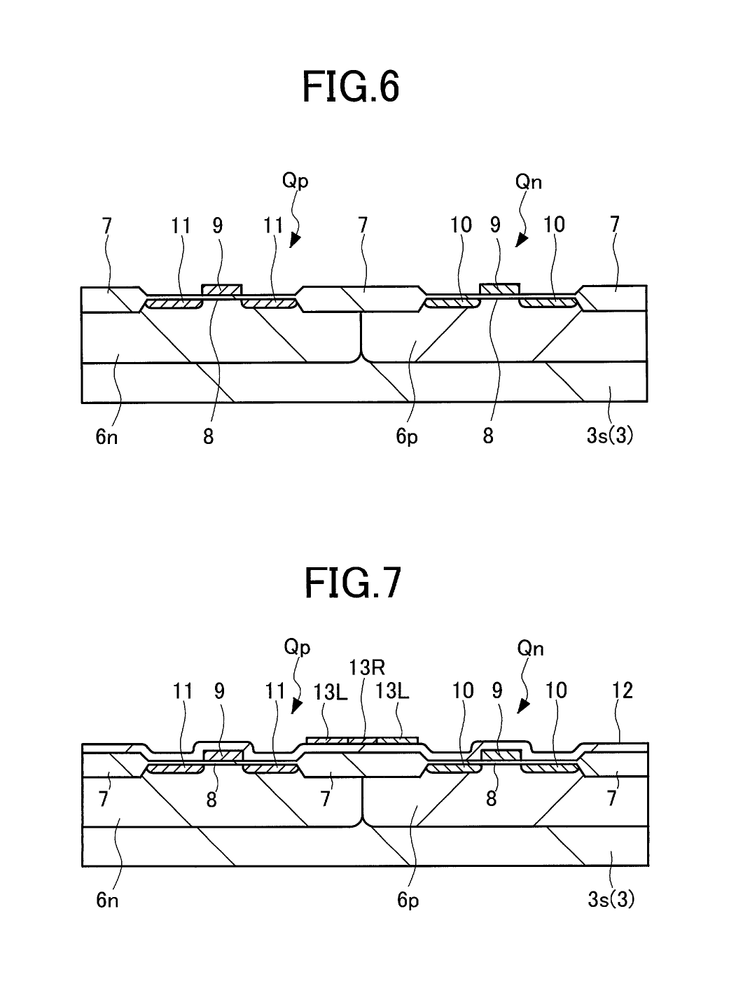

Then, the case of applying the technical thought of the present invention to the manufacturing process of a semiconductor integrated circuit device having, for example, a twin-well-type CMIS (Complementary MIS) circuit is described below by ref erring to FIGS. 6 to 9.

FIG. 6 is a sectional view of an essential portion of the semiconductor wafer 3 in the above manufacturing process. The semiconductor wafer 3 is constituted by a flat almost-circular semiconductor thin plate. A semiconductor substrate 3s constituting the semiconductor wafer 3 is made of, for example, n-type Si single crystal and, for example, an n-well 6n and a p-well 6p are formed on the substrate 3s. Phosphorus or As serving as, for example, an n-type impurity is introduced into then-well 6n. Moreover, boron serving as, for example, a p-type impurity is introduced into the p-well 6p.

A field insulation film 7 for separation formed with a silicon oxide film is formed on the principal plane (first principal plane) of the semiconductor substrate 3s through LOCOS (Local Oxidization of Silicon) or the like. It is also allowed to from a separation portion into the groove type. That is, it is also allowed to form the separation portion by embedding an insulation film in a trench formed in the depth direction of the semiconductor substrate 3s.

NMIS Qn and pMIS Qp are formed in an active area enclosed by the field insulation film 7. Gate insulation films 8 made of nMIS Qn and pMIS Qp are respectively formed with, for example, a silicon oxide film through thermal oxidation method or the like. Moreover, gate electrodes 9 made of nMIS Qn and pMIS Qp are formed by depositing a gate forming film made of low resistance polysilicon through CVD and then forming the film through the photolithography using the reduction projection aligner 5 and photolithography using the photomask 1PA1 and the normal etching. Though not restricted, the gate length is approx. 0.18 μm. An nMIS Qn semiconductor area 10 is formed in self-alignment to the gate electrodes 9 by using the gate electrodes 9 as masks and introducing phosphorus or arsenic into the semiconductor substrate 3s through ion implantation or the like. Moreover, a pMIS Qp semiconductor area 11 is formed in self-alignment to the gate electrodes 9 by using the gate electrodes 9 as masks and introducing, for example, boron into the semiconductor substrate 3s through ion implantation or the like. However, each of the gate electrodes 9 is not always formed with a single film made of low resistance polysilicon, for example, but it can be variously changed. For example, it is allowed to form each of the electrodes 9 into the so-called polycide structure in which a silicide layer made of tungsten silicide or cobalt silicide is formed on a low resistance polysilicon film or into the so-called poly-metal structure in which a metallic film made of tungsten is formed on a low resistance silicon film through a barrier conductor film made of titanium nitride or tungsten nitride.

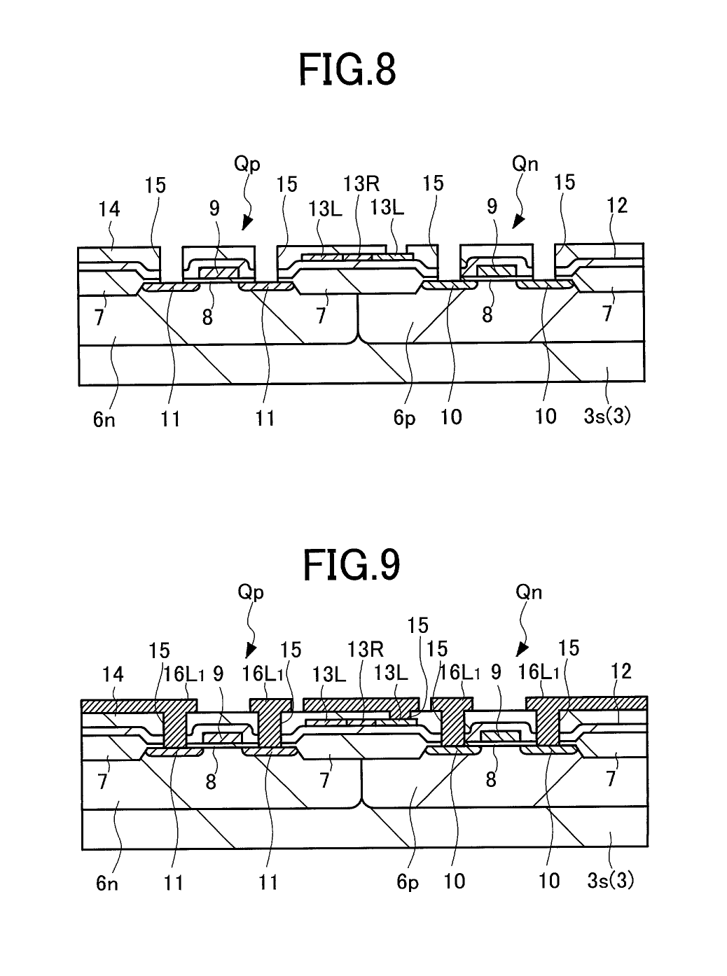

First, an interlayer dielectric film 12 formed with, for example, a silicon oxide film is deposited on the semiconductor substrate 3s through CVD or the like as shown in FIG. 7 and then, a polysilicon film is deposited on the interlayer dielectric film 12 through CVD or the like. Then, the polysilicon film is patterned through the photolithography using the above reduction projection aligner and the photomask 1PA1 and the normal etching to form a wiring 13L and a resistance 13R respectively formed with a polysilicon film by introducing an impurity into a predetermined area of the patterned polysilicon film. Thereafter, as shown in FIG. 8, an SOG (Spin On Glass) film 14 formed with, for example, a silicon-oxide film is deposited on the semiconductor substrate 3s through coating or the like to drill a via hole 15 on the interlayer dielectric film 12 and SOG film 14 so that semiconductor areas 10 and 11 and a part of the wiring 13L are exposed through the photolithography using the reduction projection aligner 5 and photomask 1PA1 and the normal etching. Moreover, a metallic film made of aluminum (Al) or an Al alloy is deposited on the semiconductor substrate 3s through sputtering or the like and patterned through the photolithography using the reduction projection aligner 5 and photomask 1PA1 and the normal etching to form a first layer wiring 16L1 as shown in FIG. 9. Thereafter, layer wirings from a second layer wiring downward are formed similarly to the case of the first layer wiring 16L1 to manufacture a semiconductor integrated circuit device.

Thus, in the case of this first embodiment, it is possible to obtain at leas any one of the following advantages.

(1) By respectively forming the opaque pattern 1b and mark pattern 1mr on the photomask 1PA1 by a resist film, it is possible to eliminate a step of etching a metallic film for forming an opaque pattern and a step of removing a resist film used as an etching mask when the metallic film is etched. Therefore, it is possible to reduce the cost of a photomask. Moreover, it is possible to improve the pattern dimension accuracy on the photomask 1PA1. Furthermore, it is possible to reduce the number of defects on the photomask 1PA1.

(2) Because of preventing various patterns formed with a resist film from being set in an area with which the holder 2 of an inspection apparatus or exposure apparatus on the circumference of the photomask 1PA1, it is possible to prevent a foreign matter due to removal or chips of the resist film on the photomask 1PA1 caused by a mechanical impact when setting the photomask 1PA1 to the inspection apparatus or exposure apparatus from being produced.

(3) According to the above Item (2), it is possible to prevent an inspection accuracy or exposure-pattern transfer accuracy from being deteriorated due to removal or chips of a resist film on the photomask 1PA1.

(4) According to the above Item (2), it is possible to prevent an imperfect short-circuit or imperfect release between patterns on the semiconductor wafer 3 due to removal or chips of a resist film on the photomask 1PA1.

(5) According to the above Items (1) to (4), it is possible to improve the reliability of a semiconductor integrated circuit device.

(6) According to the above Items (1) to (4), it is possible to improve the yield of semiconductor integrated circuit devices.

Moreover, a photomask of the present invention is effective by the above advantages even as a photomask used for trial manufacture, test, or research in order to manufacture or mass-produce a semiconductor integrated circuit device.

(Second Embodiment)

A second embodiment of the present invention describes a method for preventing a foreign matter from attaching to the photomask 1PA1 when manufacturing, using, and storing the photomask 1PA1.

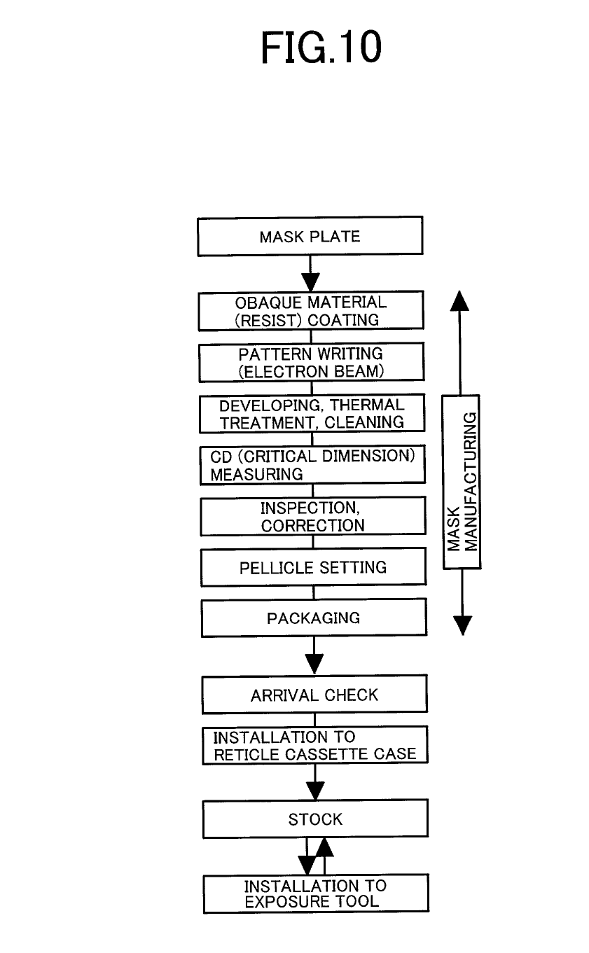

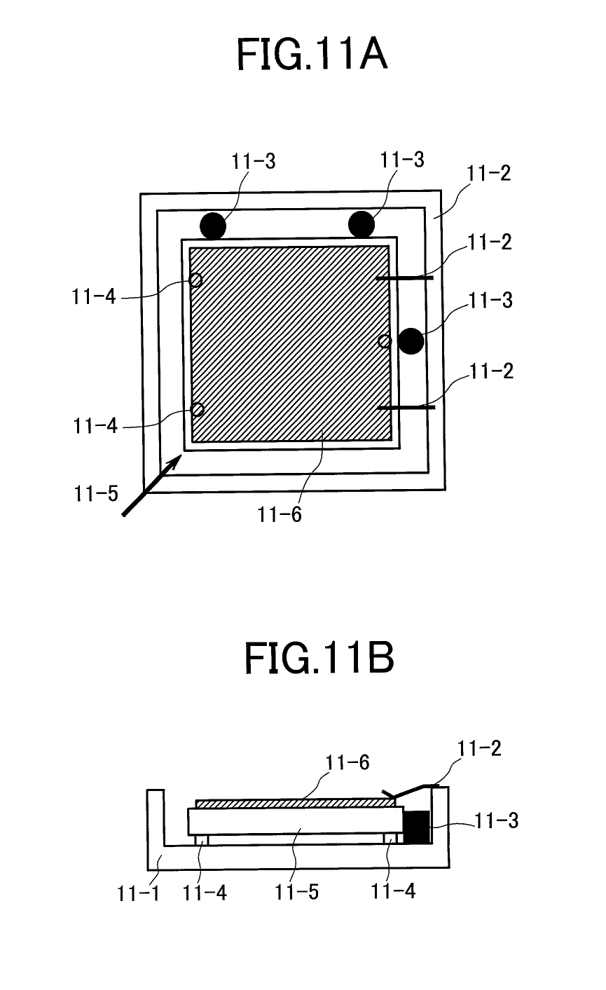

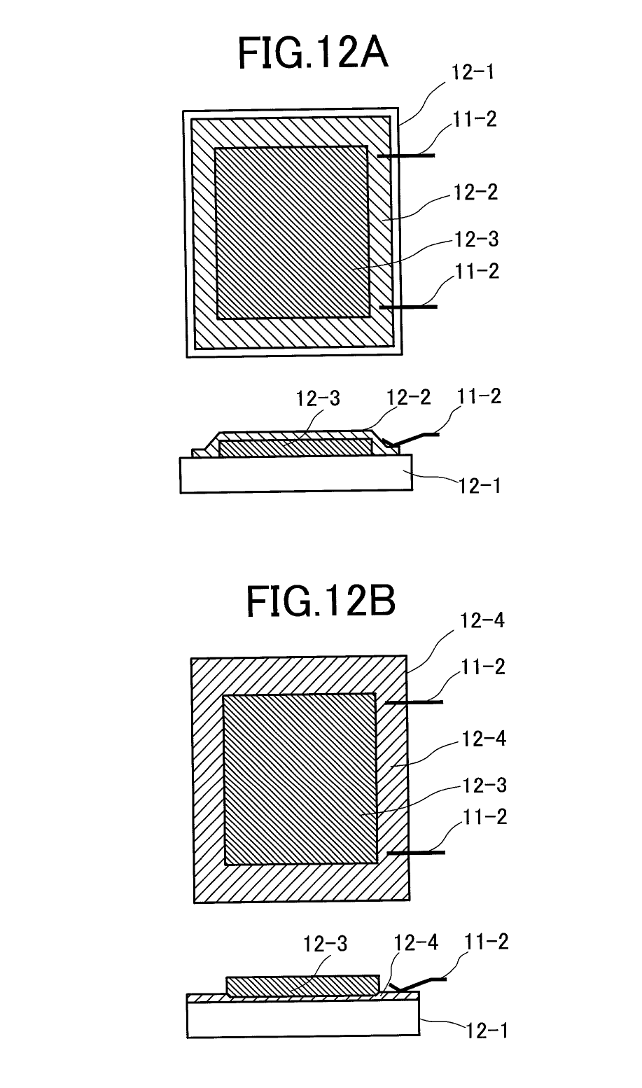

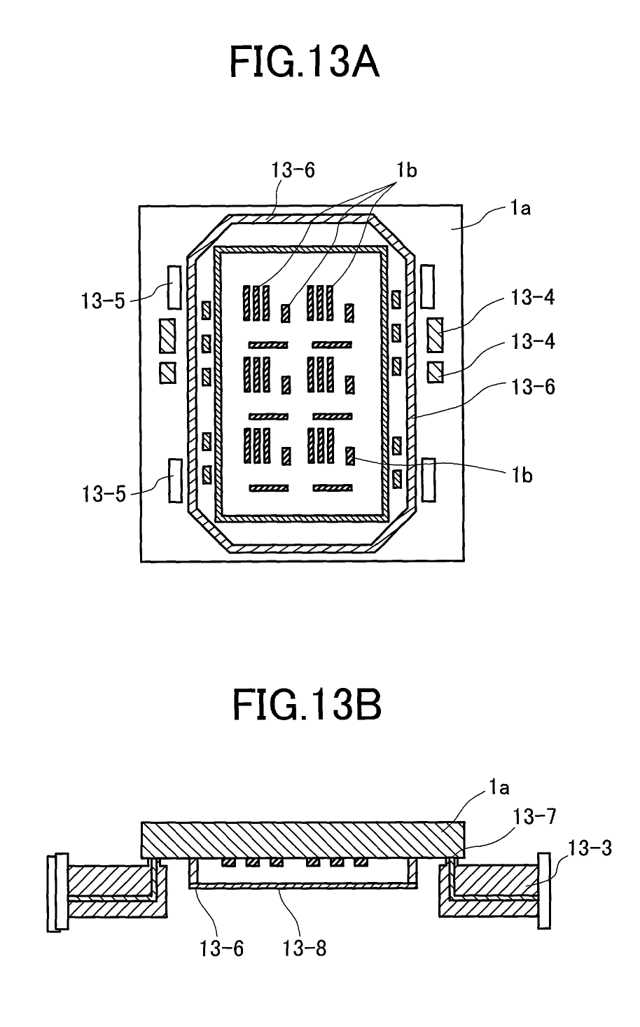

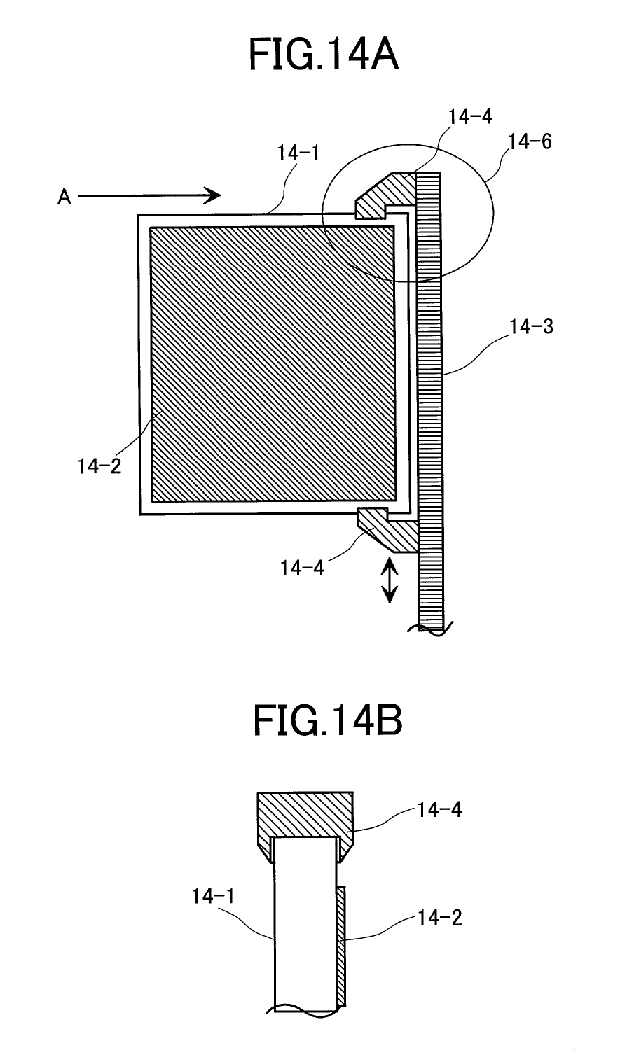

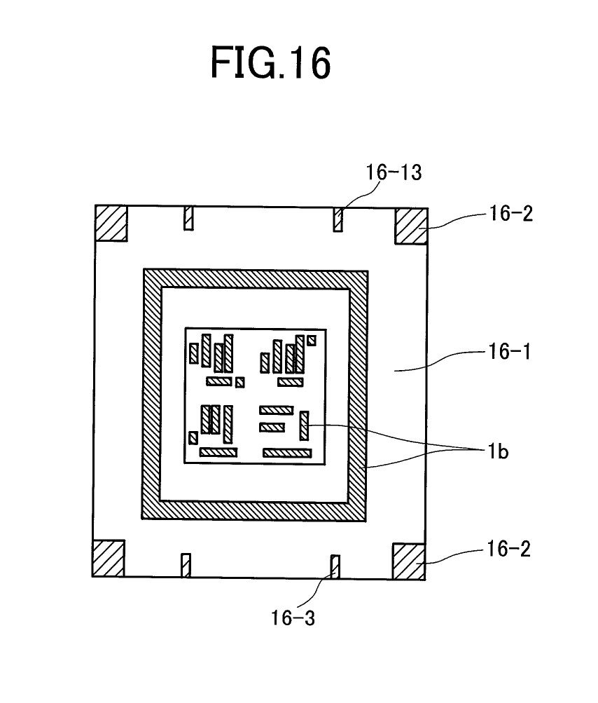

FIG. 10 shows a flow of a mask. A transparent plate is prepared and normally cleaned if necessary to form a resist film by an opaque material. A spin coater is usually used to form a resist film but a photomask of the film may be carried in contact with the back of a photomask plate. Then, a pattern is written through a step such as the normal heat treatment. A case of using electron beam writing is described below but pattern writing is not restricted to the electron beam writing. It is preferable to use a negative resist because the resist in an unnecessary area other than a functional portion in which pattern writing is performed is automatically removed. FIGS. 11A and 11B show a state of setting a photomask in an electron beam writing apparatus. The photomask is set to a mask holder 11-1 while a resist 11-6 is applied onto a transparent plate 11-5. Though the marginal portion on the circumference of a photomask causes an foreign matter, a resist can be removed by using the local coating to be described later. The back of the mask is supported by a pin 11-4, horizontal positioning is designated by a pin 11-3 and a position is fixed in accordance with three-point pin designation by applying a force to the side face of the mask from the substrate 11-5. When the resist is formed through local coating, it is allowed to hold and fix a portion on the resist-forming face of a photomask plate where the resist is not formed. Moreover, in the case of electron beam writing, when applying an electron beam to a resist, the so-called charge-up phenomenon occurs in which electrons are accumulated on the surface of the resist and causes the writing accuracy to deteriorate. To prevent the charge-up phenomenon, it is necessary to be connected to the earth by an earth pin 11-2. In the case of this mask structure, it is necessary to set a conductive material on the surface of a transparent plate or the surface of a resist because neither transparent plate 11-5 nor resist 11-6 has conductivity. When setting a transparent conductive material on the surface of a transparent plate, it may be connected to the earth from the surface of a resist. In this case, defects are produced on the surface of the resist. To prevent the defects, it is also effective for a resist 12-3 to take the earth from a portion where a conductive film 12-4 is exposed on the surface of a substrate at a portion where there is no resist around a mask as shown in FIG. 12B. As a transparent conductive film, it is possible to use, for example, an ITO (Indium Tin Oxide) film. It is unnecessary to work the transparent conductive film. Moreover, as shown in FIG. 12A, it is also effective to take the earth by avoiding a contact point with a photomask system and thereby, locally forming the resist 12-3, putting a conductive material 12-2 on the resist 12-2 and bringing an earth pin into contact with a portion on the substrate where only the conductive film is formed. In this case, no defect is produced on the resist 12-3. Because the conductive film 12-2 is removed by the subsequent development, there is not an anxiety that a foreign matter may be produced. It is preferable that the conductive film 12-2 is water-soluble when considering that the film 12-2 is removed at the same time as development. For example, ESPACER (made by Showa Denko K.K.) or aqua-SAVE (made by Mitsubishi Rayon Co., Ltd.) was used as a water-soluble conductive organic film. Then, as shown in FIG. 10, steps of development, thermal treatment, and cleaning are performed. Also in these steps, it is necessary to prevent a resist from remaining at a portion contacting with a substrate for carrying and the like. It is general that installation apparatuses and process portions of these equipments contact with the back and side face of a photomask. The same is true for the next visual inspection, dimension measurement, and correction. However, an installation apparatus and a process portion are brought into contact with the resist forming face on the surface of a mask depending on equipment as shown in FIG. 16. This is because inspections are performed by turning the surface of a photomask downward in the above case. A pin 16-3 contacts with the surface of a photomask when handling the photomask and a pin 16-2 contacts with the surface of the photomask at a mask loading position. Therefore, a structure is used in which there is no resist also at the above position. In the next step of setting a pellicle 13-8, it is necessary to exclude a resist from a point contacting with a pellicle frame 13-6 as shown in FIGS. 13A and 13B. This is because the frame may be removed together with a resist when the resist is present. Also when housing a finished photomask in a shipping photomask vessel, a structure is used in which a resist is not present at a point contacting with the photomask vessel. Because a structure with which the most circumferential portion of a mask contacts is normally used, a structure is used in which there is no resist at a circumferential portion corresponding to the above most circumferential portion. Then, a structure is used in which a resist is not present at an acceptance inspection when a photomask arrives at a photomask using section or at a contact point of a photomask vessel at the acceptance side when using the photomask. Moreover, a structure is used in which a resist is not present at a portion contacting when taking out a photomask from a photomask vessel, handling and setting the photomask to an exposure apparatus, taking out the photomask from the exposure apparatus, and housing the photomask in the photomask vessel again. FIGS. 13A and 13B show a position where an exposure apparatus contacts with a photomask. Symbol 13-5 in FIG. 13A denotes a portion for vacuum-attracting a photomask. Because there are various detection resist patterns at a portion 13-4 nearby the attracting portion 13-5, a structure for avoiding mechanical contacts is used. FIG. 13B shows a sectional view of the attracting portion. A structure is used in which there is no resist on a mask corresponding to a contact point 13-7 with a photomask of a mask stage 13-3. Moreover, when a person handles a photomask, it is allowed to use a photomask jig (handler). A structure is used in which there is no resist at a portion of the jig contacting with a photomask. FIGS. 14A and 14B show a specific example. A resist 14-2 is applied to a photomask plate 14-1. FIG. 14B shows details of a contact point with a photomask for holding an end of a mask by arms 14-4 and 14-5 when holding the photomask by a handler 14-3. FIG. 14B is an illustration of the portion 14-6 in FIG. 14A viewed from A. The photomask plate 14-1 is held by the arm 14-4. In this case, a structure is used in which the resist 14-2 is not present at a contact point because a foreign matter is produced if the resist is present at the contact point.

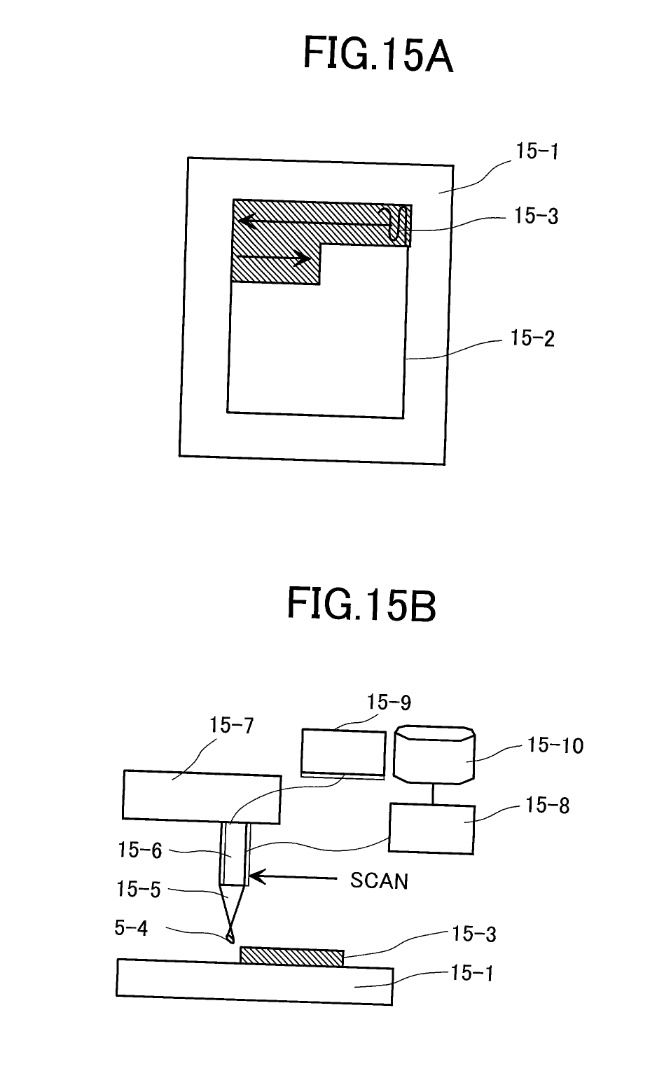

To prevent a resist from being formed on the circumference of a photomask, a method is generally known in which a resist is applied to the entire surface of a transparent plate and then the resist around the mask is removed by dissolving it by a resist solvent. In the case of this method, however, it is difficult a resist from an optional portion and therefore, the request to the mask cannot be always satisfied. A method for locally applying a resist is described below as one means of the present embodiment. FIG. 15 shows the outline of local application.

FIG. 15A shows a method for applying a resist to the surface of a mask 15-1. In the case of a method for applying a resist to a transparent plate not entirely but locally, it is allowed to hold a portion not provided with the resist on the surface of the mask 15-1 (area other than 15-2). A resist 15-3 is emitted from a nozzle 15-6 position-controlled by a position controller 15-7 and formed like a band while meandering on the surface of a wafer in the arrow directions. The resist 15-4 emitted from the front end 15-5 of the nozzle 15-6 is introduced from a resist supply system 15-9 and electrically controlled by a controller 15-8 so that emission of the resist can be turned on/off. The controller 15-8 turns on/off the emission of the resist in accordance with a database 15-10 for designating an application area. The above local-applying method makes it possible not only to avoid the mechanical contact of a resist but also to suppress the consumption of the resist and reduce the mask manufacturing cost. A resist applying method allows not only the above band-like scan application but also a method capable of applying a resist by avoiding a contact point with a photomask manufacturing system. For example, it is possible to apply a resist at a desired shape by rotating or scanning a mask and turning on/off a nozzle. Inventions made by the present inventor are specifically described above in accordance with the embodiments. However, the present invention is not restricted to the embodiments. It is needless to say that various modifications of the present invention are allowed as long as the modifications do not deviate from the gist of the present invention.

(Third embodiment)

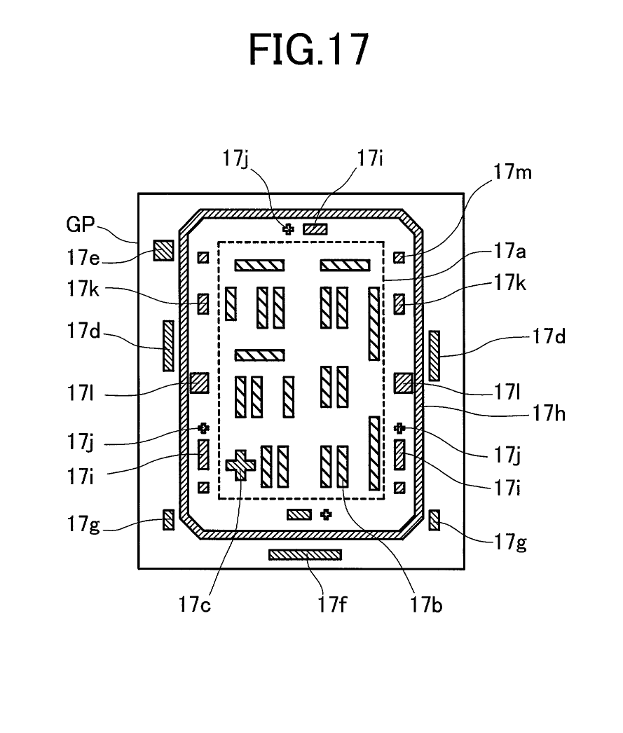

FIG. 17 shows a plan view of a photomask used for a third embodiment. This photomask is referred to as the so-called A-mask whose field portion is formed as a transparent face. A resist pattern 17b functioning as an opaque body or a dark body for shifting a phase in an integrated circuit pattern area 17a on a glass plate GP. Moreover, a wafer alignment mark 17c is also formed in the integrated circuit pattern area 17a. The wafer alignment mark serves as an alignment reference mark from the next step downward after it is transferred to a wafer. Therefore, the alignment with a photomask is performed by detecting the position of wafer alignment mark transferred to the wafer. A reticle alignment mark 17d, a mask discrimination bar-code mark 17e, a mask discrimination mark 17f, a base-line adjustment mark 17g, a pellicle frame 17h, a critical-dimension monitor pattern 17i, and a pattern-displacement monitor pattern 17j are formed outside of an integrated circuit pattern area 19a. When the resist pattern 17b is a dark film, a phase-difference and fading-rate measurement pattern 17m is added. Moreover, when using a Cr pattern to be described for a fourth and fifth embodiment together, an alignment mark for mask writing 171 serving as a mask-writing-position reference is formed with a Cr pattern. Moreover, a registration monitor pattern 17k for measuring the alignment shift between aCr pattern and a resist pattern is also formed. In the case of the present embodiment, the reticle alignment mark 17d, mask discrimination bar-code mark 17e, mask discrimination mark 17f, and base-line adjustment mark 17g are formed outside of a pellicle frame. However, it is not always necessary to form these marks outside of the frame. For example, it may be necessary to set the reticle alignment mark 17d inside of a pellicle frame depending on an exposure apparatus. Moreover, it is not always necessary to set the critical-dimension monitor pattern 17i, pattern displacement monitor pattern 17j, registration monitor pattern 17k, alignment mark for mask writing 171, and phase-difference and fading-rate measurement pattern 17m inside of a pellicle frame but it is allowed to set them outside of the frame. In this case, the reticle alignment mark 17d is a mark showing the position of a reticle, which performs alignment by monitoring the position of a wafer alignment mark and that of a reticle alignment mark.

The mask discrimination bar-code mark 17e is a mark for controlling a mask and exposure by reading the name, process, and history of a mask by a machine. The mask discrimination mark 17f is a mark in which a mask name, a lot control number, and a mask maker are written and these data values are normally written by characters so that an operator can read the data values. The base-line adjustment mark 17g is a mark for monitoring the change of an exposure apparatus with time and improving an exposure accuracy through feedback, which normally monitors alignment and a focus. The critical-dimension monitor pattern 17i is a pattern for controlling a small dimension of a mask and the pattern displacement monitor pattern 17j is a pattern for controlling a large dimension.

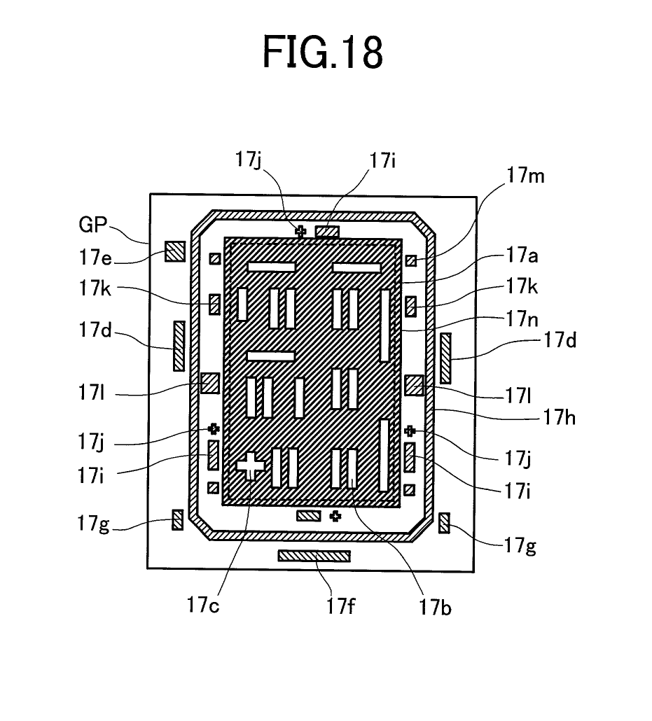

FIG. 18 shows a case of a dark field mask whose integrated circuit pattern field portion is an opaque portion, that is, the so-called B-mask. In the case of a normal dark field mask using Cr, the field portion on the circumference of the mask is also covered with Cr. In the case of the B mask, however, the circumferential field is formed by a glass face. A resist 17n is attached to an area covering the integrated circuit pattern area 17a. The area is larger than the integrated circuit pattern area 17a because of a result of considering the controllability of the masking blade of an exposure apparatus and therefore, the area is formed widely by a width of approx. 100 to 500 μm.

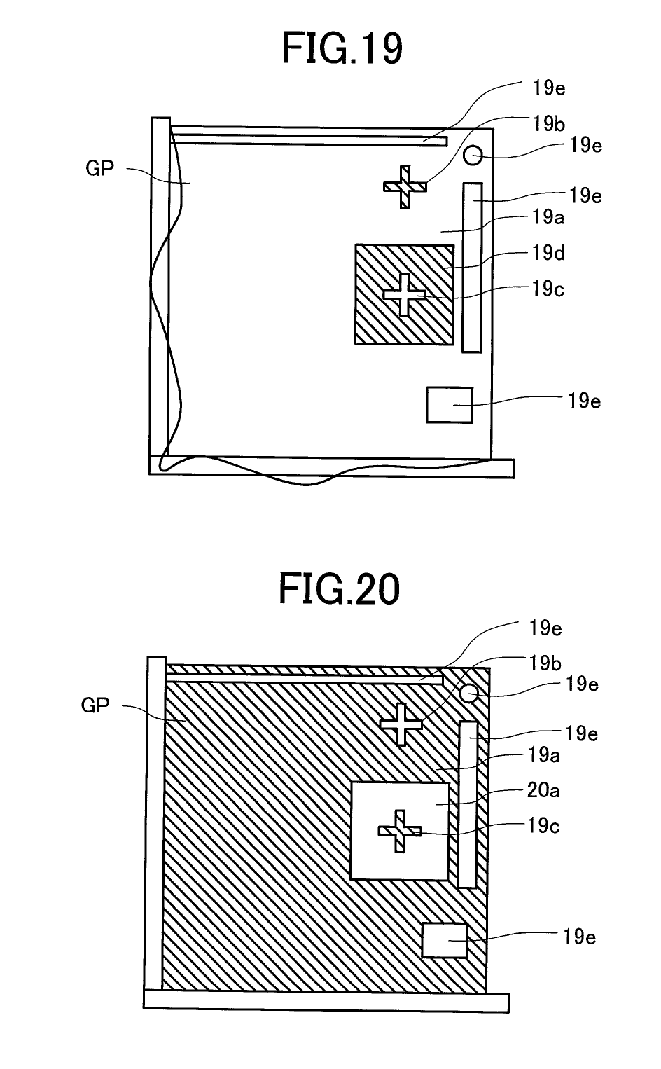

Thus, the glass-face area of the circumferential area is largely formed so that a resist does not come to a mechanical contact point. A specific example of the above mentioned is shown in FIGS. 19 and 20. FIG. 19 shows a case of a bright field mask and FIG. 20 shows a case of a dark field. In the case of a bright field, resist patterns 19b and 19d are arranged by avoiding a mechanical contact point 19e. Symbol 19c in FIGS. 19 and 20 denotes a punched pattern. A resist is attached to patterns in the case of a dark field, a resist is attached to outsides of a pattern 19a and a pattern 20a so that the contact point 19e does not cover the pattern 19b by removing the resist from the mechanical contact point 19e and changing the glass face to a metallic face. The contact point 19e is normally formed so as not to cover the pattern 20a. However, when the pattern 19c is purposed and it is allowed that the circumference of the pattern 20c is just a bright field, it is allowed that the contact point 19e covers the pattern 20a. However, also in this case, it is necessary to form the contact point 19e so that it does not cover the pattern 20a. Thus, problems of resist removal and foreign-matter production do not occur by the mechanical contact and as a result, the defect density on a pattern transferred onto a wafer is decreased and the yield of semiconductor devices manufactured by using the above mask is improved.

(Fourth Embodiment)

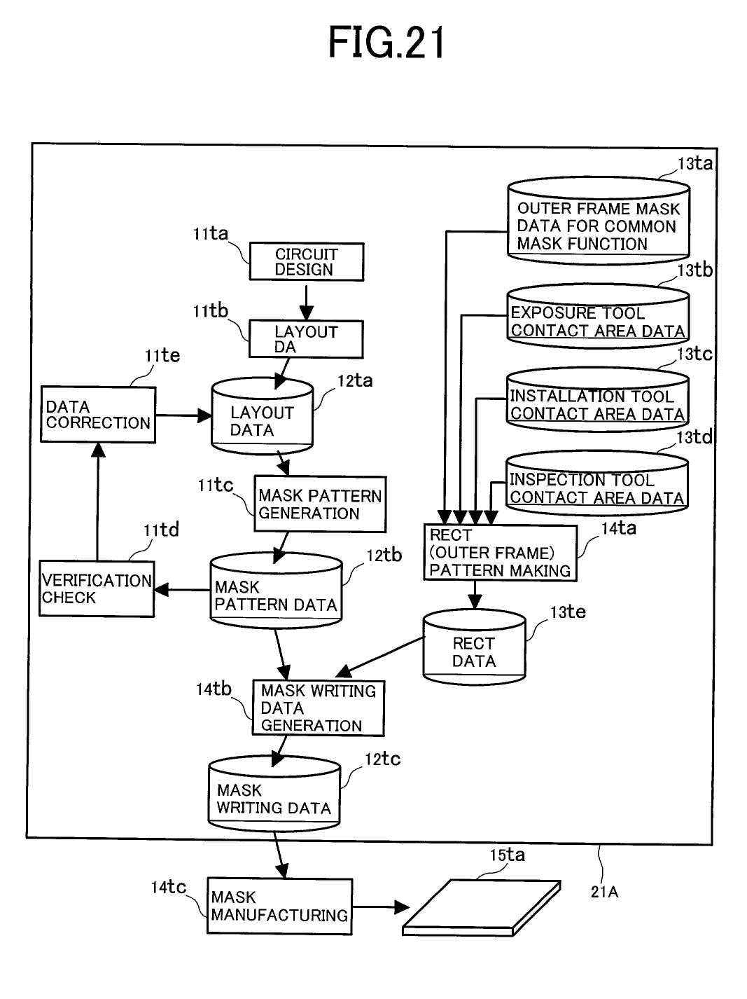

A fourth embodiment of the present invention is described below. FIG. 21 is an illustration showing the pattern-data processing for pattern-layout design and mask manufacturing for an optical mask used to manufacture a semiconductor integrated circuit device of the present invention and a configuration of equipment for performing the processing. A photomask is formed so as to serve as a mask pattern having at least a resist film and including a desired semiconductor integrated circuit pattern by forming an opening for passing exposure light on the resist film. Moreover, it is effective to add an area using a metal such as chromium as an opaque film as described later according to circumstances. In this case, the term “metal” includes a metal having an shading action such as a simplex containing a metal element, a compound, or a complex. In the case of the present mask, an opaque film formed with a resist film is not set to a portion which may contact with another unit, that is, a portion which may contact with the mask stage of an exposure apparatus, or with the support portion of a mask inspection apparatus or photomask vessel. If a pattern is necessary for these areas, the pattern is formed by using a metallic opaque film. Therefore, in the case of the pattern layout design of an optical mask of the present invention, the information showing an area for the above unit to contact with a mask can be seen.

In FIG. 21, circuit design according to the performance requested for a semiconductor device is performed in step 11ta and a mask-pattern layout is decided in step 11tb to store the layout in a file 12ta as layout data. Then, mask-pattern data is generated in step 11tc in accordance with the above data to store the data in a mask-pattern data file 12tb. At this point of time, layout verification check is performed (step 11td) and if a trouble is found, it is corrected (step 11te), and the mask-pattern data is fed back to the layout-data file. These steps are the same as steps of data processing when manufacturing a conventional chromium mask.

Moreover, the present invention uses a new step for deciding a mask pattern. That is, step 14ta is used which is a step of reading not only the mask-dedicated data 13ta for a optical-mask alignment pattern and various evaluation patterns not directly relating to the circuit pattern of a semiconductor device and for a pellicle setting area but also the data 13tb showing an area contacting with a mask stage when mounting a mask on an exposure apparatus, the data 13tc showing an area in which the mask-holding portion of a carrying and housing system contacts with a mask when housing a mask in a stock case or transferring the mask, and the data 13td showing an area in which the holding portion of an inspection apparatus contacts with a mask when inspecting the mask and step 14ta deciding rect pattern data other than integrated circuit pattern data. Moreover, the generated rect data is temporarily stored in a rect data file 13te. The above data is data for a contact area with equipment when manufacturing or using a photomask. It is allowed to store the data for a contact area as data showing an area that does not contact with equipment on the contrary to the above data.

The area shown by the data stored in the above data file tables 13ta, 13tb, 13tc and 13td is selected and used so as to finally serve as an area in which a resist film is not formed on a mask as an opaque film. To decide an area in which a resist film is not used as an opaque film, it may not be always necessary to refer to all the data in the above four types of files depending on the type of an optical mask or an exposure apparatus. However, when a step other than the above is present in which at least a part of a mask contacts in the period by the exposure apparatus from mask manufacturing up to mask pattern transfer and mask recovery, contact-point data in the step is added as data for deciding an area in which a resist film is not used as an opaque film.

Finally, in step 14tb, mask writing data is generated by capturing the data stored in the mask-pattern data file 12tb and the data stored in the rect data file 13te and stored in a file 12tc. The mask writing data is classified into a pattern in a metal opaque film for mainly defining a rect pattern and a pattern to be formed on a resist film for mainly defining a semiconductor integrated circuit device pattern. Then, a mask pattern is written in a mask manufacturing step 14tc and formed so that a mask 15ta can be manufactured.

Moreover, steps up to the step of generating the mask writing data are mainly performed by using a layout design system. FIG. 21A shows a configuration of the system necessary to manufacture a photomask of the present invention. A normal layout-design system has a circuit, sections (e.g. 11ta to 11td that perform input and edition of known coordinate data and automatic generation of pattern in accordance with functional description) for generating a layout and a mask pattern or writing data, and storage sections (e.g. 12ta to 12tc) of data. Moreover, in the case of the present invention, the following new means are included to manufacture a photomask of the present invention: storage sections (e.g. 13ta to 13td) for storing the data for a contact area, a rect-pattern generation section (e.g. 14ta can construct by the known input and edition system), storage sections (e.g. 13te) for storing the rect-pattern data, a mask writing pattern data generation section (e.g. 14tb having a function for synthesizing layout-pattern coordinate data) for synthesizing the rect pattern data with integrated circuit pattern data. A layout design system provided with the above means not only belongs to a hard ware body as a dedicated device, but can be also realized by installing software storing the above step processings as an instruction program in a normal computer or workstation.

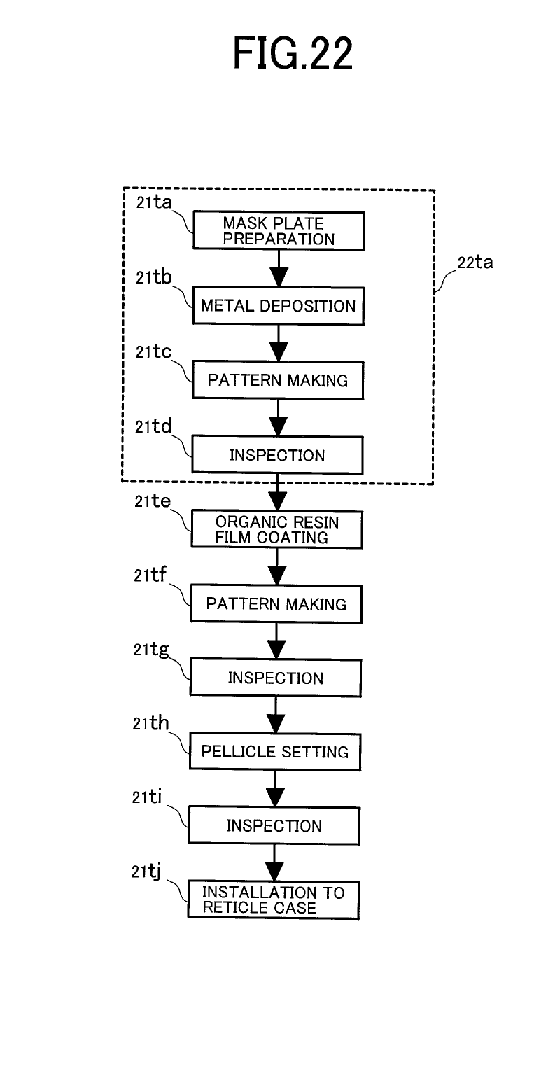

FIG. 22 shows a flow for forming a mask pattern in the above mask-manufacturing step 14tc. A mask blank is prepared in step 21ta to form a metal film for forming a metal opaque area in step 21tb. Pattern-forming step 21tc is a step of forming a pattern to be formed in the metal opaque film and comprises steps of resist application, electron-beam writing, development, and metal etching as the same manufacturing a conventional chromium mask. In this case, a metal film in an area for forming a circuit pattern by using a resist film as an opaque film is etched away. Then, cleaning and pattern inspection are performed in step 21td.

Then, in step 21te, an opaque film formed with a resist film is formed on a mask blank on which a metal opaque film and a pattern are formed. In pattern-forming step 21tf, a circuit pattern for aligning with a predetermined mark (not illustrated) formed on the metal opaque film is written and developed to form a circuit pattern of a semiconductor device. In this case, a resist film in an area in which an optical mask contacts with a member of other unit is finally removed in an area not directly relating to the circuit pattern of the semiconductor device. Thereafter, a mask is inspected (step 21tg) and a pellicle is set (step 21th). Finally, the overall inspection is performed (step 21ti) to store the mask in a photomask vessel such as a stock case (step 21tj) and prepare shipping or pattern exposure.

In this case, step 22ta up to formation of a metal opaque film and a pattern in the film is not always set whenever manufacturing a mask. That is, it is allowed to previously in step 22ta manufacture the mask original having a metal opaque area and a pattern and start with step 21te according to necessity. This is more advantageous in shortening a mask-manufacturing period.

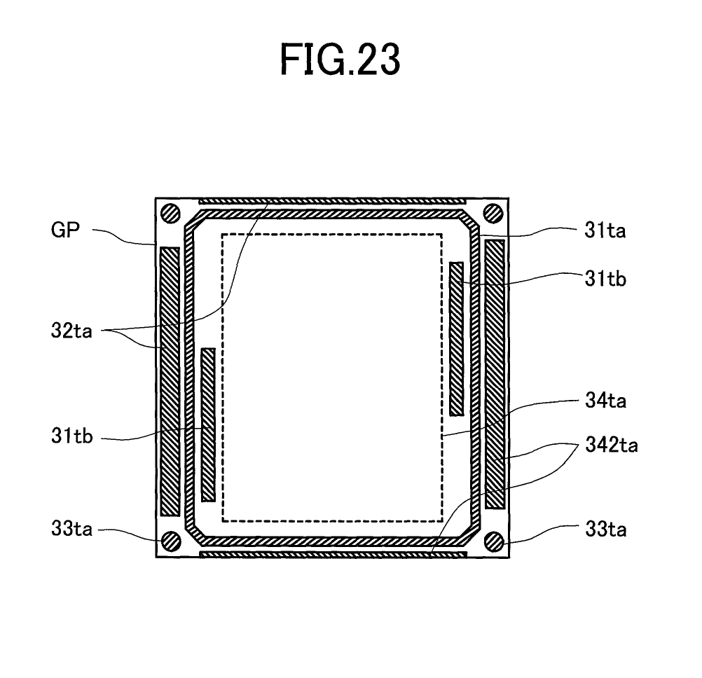

FIG. 23 is an illustration showing an area from which a resist film should be finally removed among pattern faces of an optical mask of the present invention using a mask blank GP. Symbol 31ta denotes an area to which a pellicle frame is bonded and 31tb denotes an area in which a mask alignment mark is set when mounting a mask on an exposure apparatus. These areas are defined by the data stored in a data file 13ta shown in FIG. 21. Moreover, symbol 32ta denotes a contact point with handling means and stage attraction face when setting a mask to the mask stage of an exposure apparatus. Moreover, a portion directly contacting with a support portion when setting a pattern-formed mask to a mast inspection apparatus is almost the same area. Symbol 33ta denotes a portion where the mask holder of a mask stock case contacts with the pattern face of an optical mask. The data showing these areas is stored in the data files 13tb, 13tc, and 13td shown in FIG. 21. The area 34ta shown by a broken line is an area for forming a circuit pattern by a resist film.

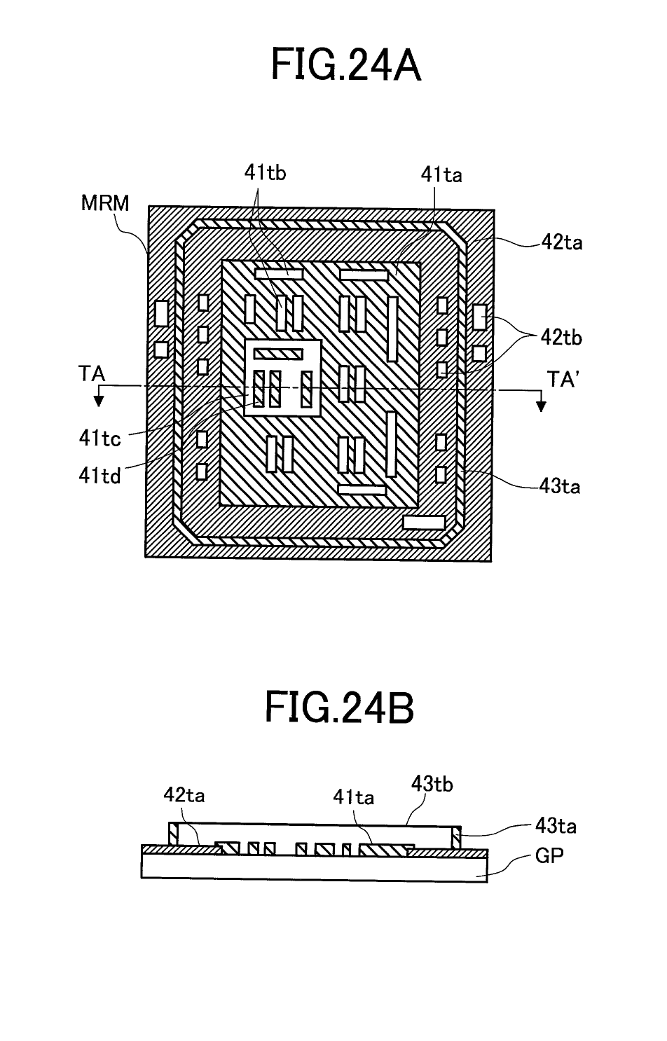

FIG. 24 is an illustration schematically showing a finished optical mask MRM. This mask is constituted by a mask blank GP, a resist opaque area 41ta and a transparent pattern 41tb formed in the area 41ta, a metal opaque area 42at and a transparent pattern 42tb formed in the area 42ta, a pellicle frame 43at, and a pellicle 43tb or the like. Moreover, in the case of the present embodiment, a transparent area 41tc is formed on a part of the resist opaque area 41ta and an area having a resist opaque pattern 41td is included in the area 41tc. In the case of the present embodiment, a resist film is present in the illustrated area 41ta and is naturally formed so as to avoid an area from which the resist film shown in FIG. 23 should be removed.

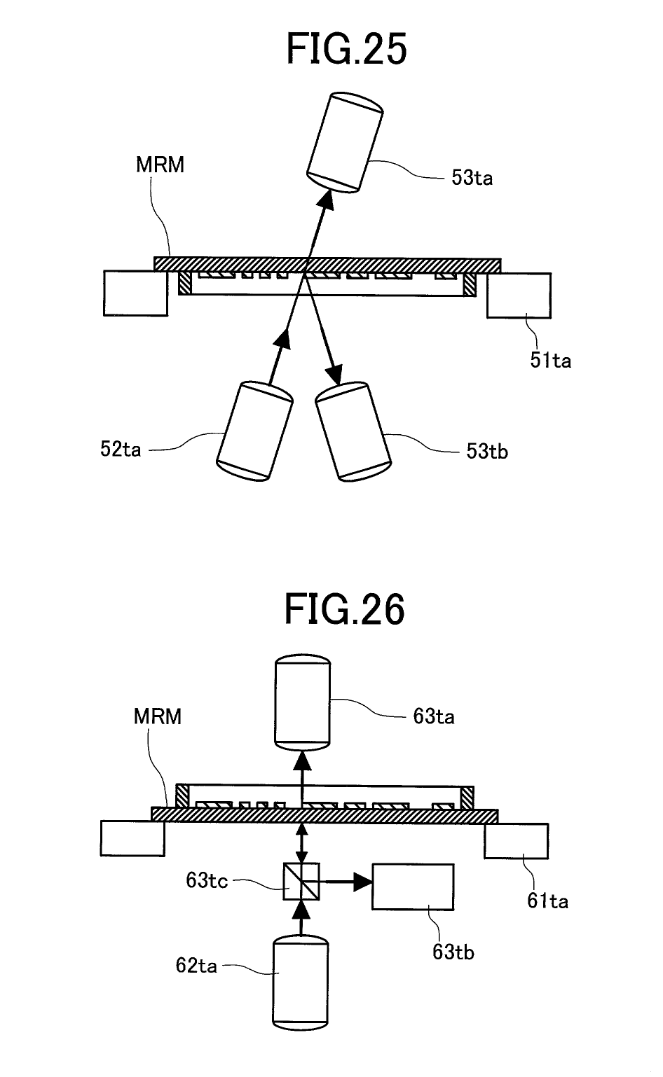

A specific example of an area from which a resist film should be removed is described below. FIG. 25 is an illustration showing a state of mounting an optical mask MRM of the present invention on the stage 51ta of a mask inspection apparatus. Detection light emitted from a light source 52ta is applied to A mask from a pattern face and mask-transmitted light is detected by a first detector 53ta and reflected light is detected by a second detector 53tb to mainly detect defects on a pattern formed on a metal opaque film and foreign matters on the overall pattern face. Because the stage 51ta of the mask inspection apparatus directly contacts with the mask, it is made possible to store the data showing the area in the data file 13td shown in FIG. 21.

FIG. 26 is an illustration showing a state of setting an optical mask MRM of the present invention to the stage 61ta of another inspection apparatus. In this case, detection light emitted from a light source 62ta is vertically applied to an optical mask, and mask-transmitted light is detected by a first detector 63ta and reflected light is detected by a second detector 63tb via a beam splitter 63tc. In this case, because the mask stage 61ta of the inspection apparatus contacts with a face opposite to the pattern face of the optical mask of the present invention, the face is not always an area from which a resist film should be removed. However, because handling means for handling and setting a mask on a stage may contact with a pattern face, the contact area is also set so that it can be stored in the data file 13tc shown in FIG. 21.

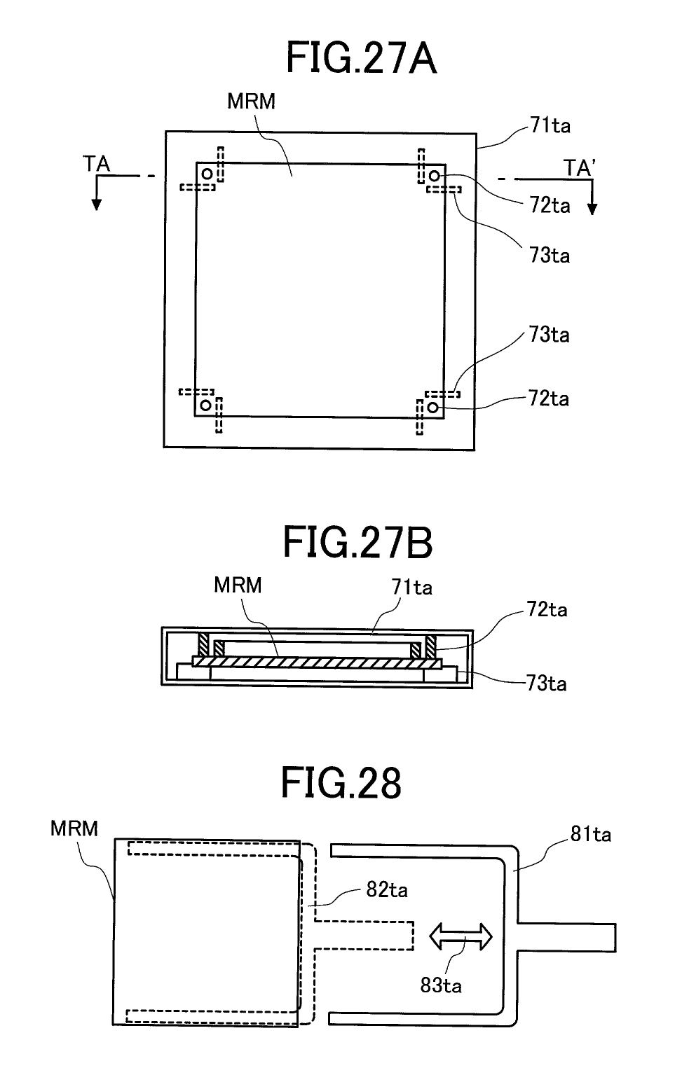

FIGS. 27A and 27B show a case in which the mask holder of a mask stock case contacts with the pattern face of an optical mask. An optical mask MRM of the present invention is stored in a stock case 71ta. The support portion 73ta of the case contacts with a face opposite to the pattern face of the optical mask MRM. To fix the mask, a support portion 72ta having a small area contacts with four corners of the mask at the pattern face side. Therefore, the data showing the contact points is set so that it can be stored in the data file 13tc shown in FIG. 21 as an area from which a resist film should be removed.

FIG. 28 is an illustration showing a state in which handling means 81ta moves to the position of 82ta in the direction of an arrow 83ta to prepare handling of an optical mask MRM, to carry the optical mask of the present invention onto the mask stage of the projection aligner. In this case, a part of the handling means 81ta may contact with a part of the pattern face of the optical mask MRM. Moreover, when the mask is set on the mask stage of a projection aligner, the circumferential portion of a patter face is normally vacuum-attracted. Therefore, an attraction portion contacts with the pattern face. The data showing the areas of these contact points is stored in the data file 13tb shown in FIG. 21.

As described above, in all steps from a step of manufacturing an optical mask including a resist film as an opaque portion until a step of using the optical mask, the data showing an area in which the above mask pattern face directly contacts with another unit is stored so that the data can be seen in a mask pattern data generation step. As a result, it is possible to completely remove a resist film in an area in which a pattern face directly contacts with another unit and prevent a foreign matter from being produced due to contact. Therefore, the yield of manufactured semiconductor integrated circuit devices is improved. Moreover, it is possible to accurately form a pattern by mounting the above optical mask on the mask stage of a projection aligner and transferring a pattern onto a semiconductor substrate and moreover accurately manufacture semiconductor integrated circuit devices.

For the present embodiment, a case is described in which a resist film serves as an opaque film. Moreover, the same advantage can be also obtained from the case of a dark film in which a resist film shifts a phase.

(Fifth Embodiment)

An embodiment is described below in which the pattern of a desired semiconductor integrated circuit device is transferred by using an optical mask obtained by combining a pattern formed on a resist film with a pattern formed a metal opaque film.

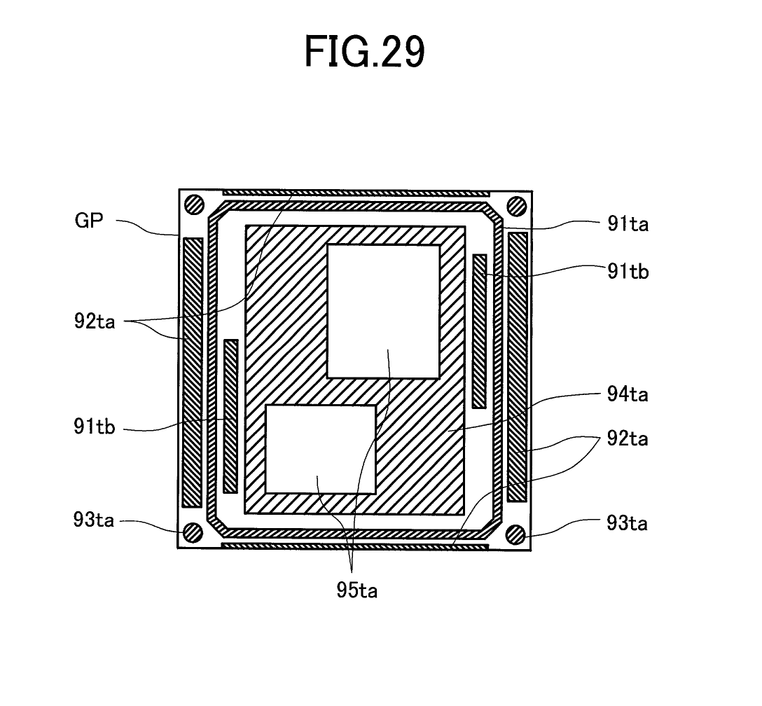

FIG. 29 is an illustration showing another embodiment of an optical mask used to manufacture a semiconductor integrated circuit device of the present invention, which corresponds to the plan view (FIG. 23) of the optical mask described for the fourth embodiment. That is, symbol 91ta denotes an area in which a pellicle frame will be set, 91tb denotes an area in which a mask alignment mark will be set when setting a mask to an exposure apparatus, 92ta denotes a contact point with handling means or a stage attraction face when setting a mask to the mask stage of an exposure apparatus, and 93ta denotes a point where the mask holder of a mask stock case contacts with the pattern face of an optical mask. These are illustrations showing areas from which a resist film should be finally removed among pattern faces on a mask blank GP. In this case, the difference from FIG. 23 showing the fourth embodiment is the fact that an area 94ta from which a resist film should be removed is present also in the pattern area of a semiconductor integrated circuit device. The area is an area in which a circuit pattern is formed by using a metal film as an opaque film. The area shown by 95ta serves as an area in which a resist film can be used as an opaque film in the pattern area of a semiconductor integrated circuit device. That is, the pattern of a desired semiconductor integrated circuit device is transferred onto a semiconductor substrate (wafer) by using an optical mask obtained by combining a pattern formed on the resist film with a pattern formed on a metal opaque film. The pattern formed on the resist film is used as a pattern for changing a pattern shape every a small number of wafers and the pattern formed on the metal opaque film is used as a pattern common to exposure of a large number of wafers.

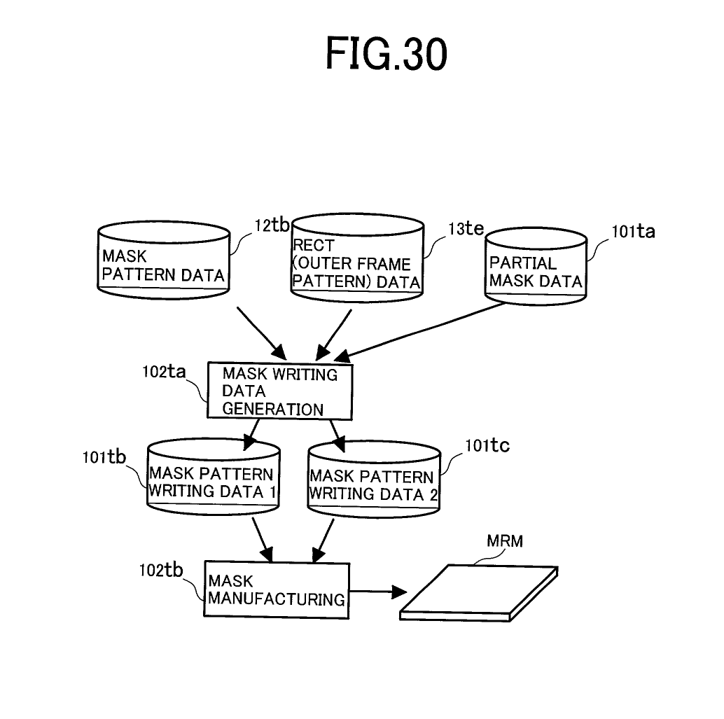

FIG. 30 is an illustration showing a flow of data processing when manufacturing an optical mask in which a desired semiconductor integrated circuit device pattern as describe above is formed with two types of opaque films such as a metal film and a resist film. A mask-pattern data file 12tb and a rect data file 13te are the same as those in FIG. 21 and steps up to the step of generating these data files are common to the steps shown in FIG. 21. Therefore, they are omitted in FIG. 30. In this case, a new local mask data file 101ta is prepared. The file 101ta stores a portion using a metal as an opaque film among semiconductor integrated circuit device patterns. That is, the file 101ta stores the data showing the contour of the area 95ta shown in FIG. 29 and its internal pattern data. Wiring data 1 to be formed on a metal opaque film is stored in a file 101tb and writing data 2 to be formed on a resist opaque film is stored in a file 101tc in a mask-writing-data generation step 102ta by referring to the local mask data file 101ta, a mask pattern data file 102tb, and the rect data file 13te. The writing data 1 is writing data obtained by removing pattern data to be formed on the resist opaque film from the whole mask data constituted by rect data and a semiconductor integrated circuit device pattern. In a mask manufacturing step 102tb same as the flow shown in FIG. 22, an optical mask MRM is manufactured by successively using the above writing data 1 and the writing data 2 similarly to the case of the fourth embodiment.

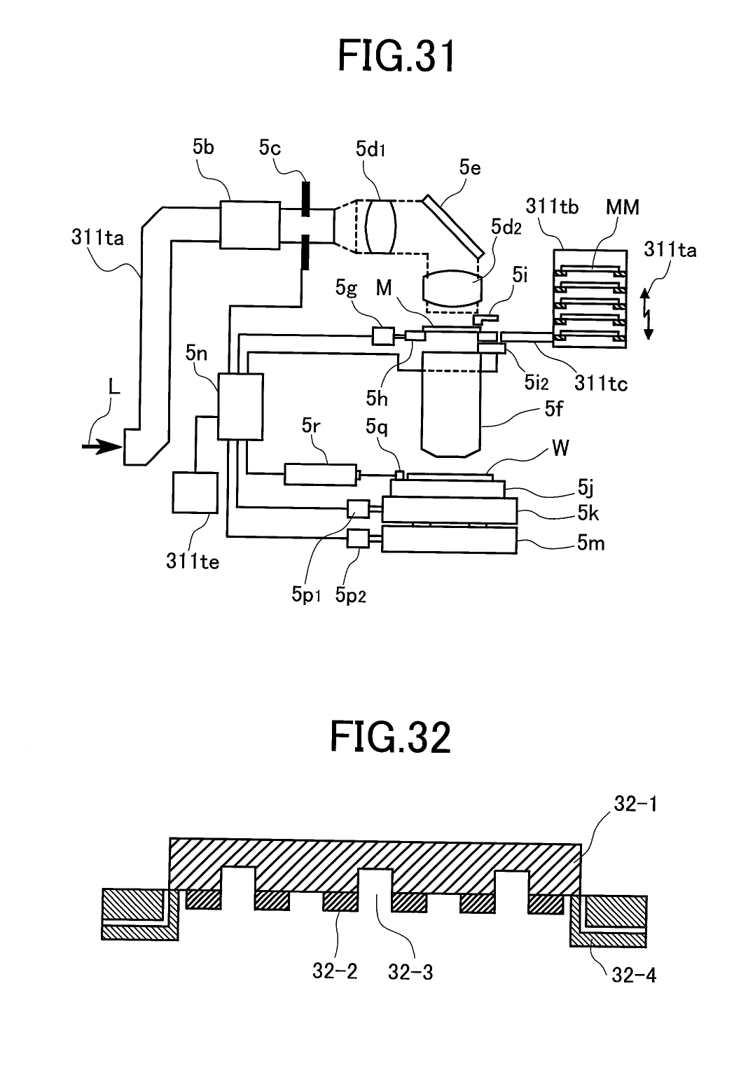

The pattern on the above mask MRM is transferred onto a semiconductor wafer by using a reduction projection aligner. FIG. 31 is an illustration showing a schematic configuration of a reduction projection aligner, in which a portion same as an equipment portion shown in FIG. 5 is provided with the same number. The reduction projection aligner has an optical route 311ta for guiding illumination light L emitted from a light source, a fly eye lens 5b, an illumination pattern control aperture 5c, condenser lenses 5d1 and 5d2, a mirror 5e, a mask stage 5h, a projection lens 5f and a wafer stage 5j and so on. A mask M is set on the mask stage 5h and a semiconductor wafer W is set on the wafer stage 5j to transfer a pattern on the mask M onto the wafer W. The light L emitted from an exposure light source uses an ArF excimer laser beam (wavelength of 193 nm) in this case. However, the same advantage is obtained also when using a KrF excimer laser beam (wavelength of 248 nm), an F₂ laser beam (wavelength of 157 nm), a g-beam (wavelength of 436 nm), or i-beam (wavelength of 365 nm). The position of the mask stage 5h is controlled by the mask-position controller 5g. The wafer stage 5j is positioned by driving the Z sage 5k by the driver 5p1 and driving the XY stage 5m by the driver 5p2. The above drivers are operated in accordance with a control instruction output from the main controller 5n. To execute repetitive exposure, the position of the wafer W is obtained by detecting the position of the mirror 5q fixed onto the wafer stage 5j by a laser measuring system 5r. The position information thus obtained is transmitted to the main controller 5n and the main controller 5n drives the drivers 5p1 and 5p2 in accordance with the information. Moreover, the main controller 5n is electrically connected with a network system 311te to realize remote control of a state of an exposure apparatus.

The mask M is selected out of masks MM housed in a mask cassette 311tb and taken out so that it does not contact with a resist. That is, the mask cassette 311tb vertically moves in the direction of an arrow 311td to set a mask onto the mask stage 5h from a predetermined position through a mask handling route 311tc. In this case, the positioning mark of the mask M set by the position monitor tool 5i and a light-receiving section 5i2 for receiving detection light is detected to position the mask. In the case of the present embodiment, because detection light uses the light having a wavelength of 670 nm, the detection light passes through a resist film used for an optical mask of the present invention. Therefore, a mask-positioning mark uses a mark formed on a metal opaque film. However, when using the light having the same wavelength as exposure light for detection light, it is possible to use a mask-positioning mark formed with a resist film if a resist film sufficiently reduce the intensity of detection light. After exposing a semiconductor wafer, it is necessary to set a new photomask on the mask stage 5h in order to transfer the photomask to the same wafer. In this case, it is also possible to take out a photomask provided with a resist from a stage so as not to contact with the resist and house the photomask in the mask cassette 311tb again.

As described above, it is possible to manufacture semiconductor integrated circuit devices at a high yield by repeating the pattern transfer using a mask manufactured for the present invention and forming a circuit pattern at a short TAT.

(Sixth Embodiment)

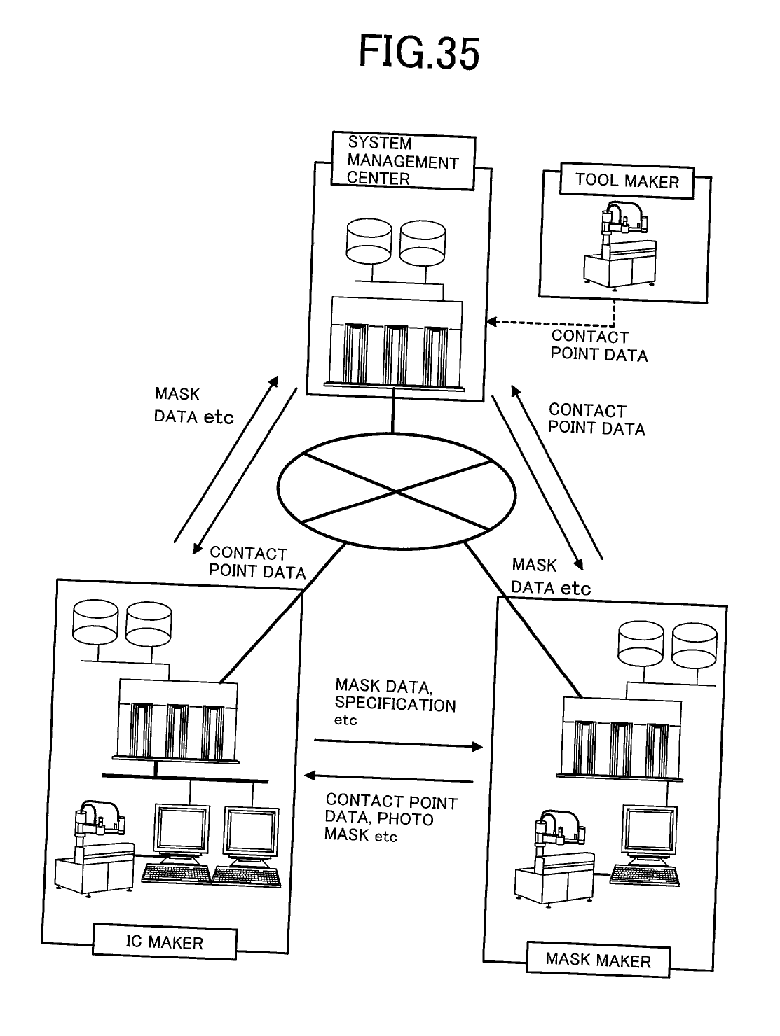

An embodiment for management or usage of the data about a contact area with the manufacturing system described for the fourth or fifth embodiment is described below. FIG. 35 is a system block diagram of management or usage of the data about an area contacting with a manufacturing system or the like performed through a telecommunication line. A designer of a maker 35pa of a semiconductor integrated circuit device (hereafter referred to as IC maker) generates the rect pattern data (e.g. 13te in FIG. 21) necessary to form a photomask as described for the fourth embodiment. In this case, the data (e.g. 13tb to 13td in FIG. 21) for contact points with a photomask manufacturing system 35eb owned by a photomask maker 35pb (hereafter referred to as mask maker) is previously obtained. At the mask maker 35pb, the following are set in order to transmit contact-area data to the IC maker 35pa: at least a database 35db storing contact area data, a mask-related database group 35fb for process history, delivery-date control, shipping information, and customer information or a host computer 35hb, and a terminal 35sb (terminal for control of photomask manufacturing system 35eb may be included) connected to the database group 35fb or host computer 35hb. It is preferable that a mask maker adds or updates the above contact-area data when introducing a new manufacturing system or at a proper timing. The contact-point data is transmitted to the IC maker 35pa through a telecommunication line 35i. The telecommunication line 35i can be a leased line, a digital communication network, or Internet for realizing communication between an IC maker and a mask maker independently of radio or cable. The contact-point data transmitted from a mask maker is stored in a database 35da through a host computer 35ha. The host computer 35ha is connected with a plurality of terminals 35ta (or terminal 35sa for control of IC manufacturing system 35ea). The host computer 35ha and the terminals 35ta respectively have a function as a circuit or a layout design apparatus and therefore, a designer can design a desired IC or its layout through the terminals 35ta. When the designer generates rect pattern data in the above design, he can read the contact-point data from the database 35da through the host computer 35ha and properly use the data in accordance with the specification of an IC. An IC maker can manufacture a desired IC by using the above contact-point data. The mask data generated after generating rect pattern data is stored as one database of the mask-related database group 35fa of the IC maker through the host computer. It is effective for reduction of the cost of IC design to collectively manage contact-point data and rect pattern data generated by using the contact-point data as a database group and share the database group by designers. That is, it is possible to prevent duplicate work because the same data can be used when using the same rect pattern data again or when a plurality of designers jointly design an IC. Moreover, it is effective to make it possible to access the above database groups 35fa and 35fb sequentially or in real time from the IC maker 35pa and mask maker 35pb. Thereby, the mask maker can obtain the progress state of IC photomask design and prepare for the manufacturing schedule, necessary materials, or manufacturing-line setting of the photomask while the IC maker can obtain the progress state of photomask manufacturing and the delivery date of a photomask and prepare for the IC manufacturing schedule and line. That is, it is possible to expect the reduction of the number of manufacturing days and manufacturing cost.

On the contrary to the above mentioned, the mask maker can obtain the data for contact points with a semiconductor manufacturing system from the IC maker and can design a layout or manage the data. Furthermore, it is allowed to establish a system management institution 35pc for managing in common contact-point data and mask data or the like. The management institution 35pc can be a natural person, a legal person, a corporation, a foundation, or an organization. So as to manage the system management institution 35pc, the contact-point data and mask data or the like, the system management institution 35pc also has at least a host computer 35hc, a database 35dc for contact-point data, or a mask-data-management-related database group 35fc so as to be able to accept or provide contact-point data or mask data through the telecommunication 35i in accordance with a request from he IC maker 35pa or mask maker 35pb. It is possible to establish the system management institution 35pc between two parties such as an IC maker and a mask maker transacting with each other or establish the institution 35pc as a management institution including pluralities of IC makers and mask makers. Sharing contact-point data between companies is effective because it is possible to totally reduce the mask manufacturing cost and the semiconductor manufacturing cost in the semiconductor industry business. Moreover, providing contact-point for the system management institution 35pc by participation of a semiconductor manufacturing system maker and host-mask-tool maker 35pd is more effective for sharing of the above contact-point data.

Because a resist does not contact with other equipment by the present invention, the number of foreign matters decreases and the manufacturing yield of devices or photomasks is improved.

Other aspects of the present invention are defined as follows:

(1). A manufacturing method of a photomask having a pattern formed with a resist, comprising:

a step of preparing a transparent plate;

a step of locally applying a resist on at least one face of the transparent plate; and

a step of forming a pattern on the resist.

(2). The photomask manufacturing method according to the above (1), wherein a transparent plate with a conductive material on its surface is prepared in the step of preparing the transparent plate.

(3). The photomask manufacturing method according to the above (1), wherein a resist is applied so as not to be provided for at least a contact point with photomask manufacturing system in the step of locally applying a resist.

(4). A manufacturing method of a photomask having a pattern formed with a resist, comprising:

a step of preparing a photomask plate in which the resist is locally applied on at least one face of a transparent plate; and

a step of holding the photomask so that the resist does not contact with the holding mechanism of a pattern exposure apparatus or a pattern writing apparatus and of performing pattern exposure or pattern writing.

(5). The photomask manufacturing method according to the above (4), wherein the resist is applied in accordance with a scan application method.

(6). The photomask manufacturing method according to the above (4), wherein the pattern writing uses electron beam writing.

(7). The photomask manufacturing method according to the above (6), further comprising a step of applying a conductive material to the photomask plate before performing the electron beam writing.

(8). A manufacturing method of a photomask provided with a resist comprising:

a step of preparing a transparent plate with a resist applied on it; and

a step of performing pattern exposure or pattern writing for the resist and forming a pattern so as not to provide a resist for a contact point with a photomask manufacturing system.

(9). A manufacturing method of a photomask having a pattern formed with a resist, comprising:

a step of preparing a photomask plate with a resist applied on at least one face of a transparent plate;

a step of forming a pattern on the resist;

a step of holding the photomask plate so that the resist does not contact with the holding mechanism of a photomask dimension measurement apparatus and of measuring dimensions.

(10). A manufacturing method of a photomask having a pattern formed with a resist, comprising:

a step of preparing a photomask plate with the resist applied on at least one face of a transparent plate;

a step of forming a pattern on the resist; and

a step of holding the photomask plate so that the resist does not contact with the holding mechanism of a photomask inspection apparatus to inspect the photomask plate.

(11). A manufacturing method of a photomask having a pattern formed with a resist, comprising:

a step of preparing a photomask plate with the resist applied on at least one face of a transparent plate;

a step of forming a pattern on the resist; and

a step of holding the photomask plate so that the resist does not contact with the holding mechanism of a photomask correction apparatus to correct the photomask plate.

(12). A manufacturing method of a photomask having a pattern formed with a resist, comprising:

a step of preparing a photomask plate with the resist applied on at least one face of a transparent plate;

a step of forming a pattern on the resist; and

a step of holding the photomask plate so that the resist does not contact with the holding mechanism of a photomask installation apparatus to carry the photomask plate.

(13). A manufacturing method of a photomask having a pattern formed with a resist, comprising:

a step of preparing a photomask plate with the resist applied on at least one face of a transparent plate;

a step of forming a pattern on the resist; and

a step of holding and handling the photomask plate so as not to contact with the resist.

(14). The photomask manufacturing method according to the above (13), wherein a photomask jig is used in the step of holding and handling the photomask plate so as not to contact with a resist.

(15). The photomask manufacturing method according to the above (9), wherein the photomask plate is held on the face in the step of holding the photomask plate so as not to contact with a resist.

(16). A manufacturing method of a photomask-included vessel comprising:

a step of preparing a photomask having a pattern formed with a resist on at least one face of a transparent plate; and

a step of housing the photomask in a photomask vessel so that a resist does not contact with a photomask vessel.

(17). A manufacturing method of a photomask having a pattern formed with a resist, comprising:

a step of preparing a photomask plate having a pattern formed with the resist on at least one face of a transparent plate; and

a step of setting a pellicle frame to the photomask plate so as not to contact with the resist.

(18). A device manufacturing method comprising:

a step of preparing a photomask having a pattern formed with a resist on at least one face of a transparent plate; and

a step of holding the photomask so that the resist does not contact with the holding mechanism of an exposure apparatus and of exposing a workpiece for a device.

(19). The device manufacturing method according to the above (18), wherein the device is a semiconductor integrated circuit device and the workpiece is a semiconductor wafer.

(20). The device manufacturing method according to the above (18), wherein a portion on the face of the photomask where the resist is not formed is hold and exposed.

(21). A manufacturing method of a semiconductor integrated circuit device, comprising:

a step of preparing a photomask having a pattern formed with a resist and a pattern formed with a metal on a transparent plate; and

a step of holding the photomask by the pattern portion formed with the metal so that the resist does not contact with the holding mechanism of a reduction projection aligner and of exposing a semiconductor wafer.

(22). A manufacturing method of a semiconductor integrated circuit device, comprising:

a step of preparing a photomask plate with a resist applied on a photomask plate;

a step of patterning the resist on the photomask plate and forming a photomask having a pattern formed with the resist; and

a step of holding the photomask on the holding mechanism of a reduction projection aligner so as not to contact with the resist and of exposing a semiconductor wafer.

(23). The semiconductor integrated circuit device manufacturing method according to the above (22), wherein the face for holding the photomask is formed by locally applying the resist.

(24). The semiconductor integrated circuit device manufacturing method according to the above (22), wherein the face for holding the photomask is formed by patterning the resist.

(25). A manufacturing method of a semiconductor integrated circuit device, comprising:

a step of generating layout pattern data for a photomask provided with a resist by using data for a circuit pattern of a semiconductor device and data for a contact area with a reduction projection aligner;

a step of setting the photomask provided with the resist formed by using the layout pattern data to a reduction projection aligner and of exposing a semiconductor wafer.

(26). A manufacturing method for the device according to the above (18), wherein the exposure uses any one of g-beam, i-beam, ArF excimer laser beam, KrF excimer laser beam, and F₂ laser beam.

(27). A semiconductor integrated circuit device layout design apparatus comprising:

means for storing a pattern data for the semiconductor integrated circuit;

means for storing data for a contact area with a mask manufacturing system or an exposure apparatus for manufacturing a semiconductor integrated circuit device; and

means for generating a layout pattern data for a photomask provided with a resist by using the pattern data for the semiconductor integrated circuit and the data for the contact area.

(28). A method for manufacturing a semiconductor integrated circuit device by using a photomask provided with a resist designed by the layout design apparatus of the above (27).

(29). A semiconductor integrated circuit device layout design method, comprising:

a step of storing a pattern data for a semiconductor integrated circuit;

a step of storing data for a contact area with a photomask manufacturing system or an exposure apparatus for manufacturing a semiconductor integrated circuit device; and

a step of generating a layout pattern data for a photomask provided with a resist by using the pattern data for the semiconductor integrated circuit and the data for the contact area.

(30). A method of manufacturing a semiconductor integrated circuit device, comprising:

a step of taking out a photomask provided with a resist from a photomask vessel so as not to contact with the resist; and

a step of setting the photomask to a reduction projection aligner and of exposing a semiconductor wafer.

(31). A method of manufacturing a semiconductor integrated circuit device, comprising:

a step of taking out a photomask provided with a resist from a reduction projection aligner so as not to contact with the resist after exposing a semiconductor wafer and of housing the photomask in a photomask vessel;

a step of setting a photomask different from the photomask provided with the resist from the photomask vessel to a reduction projection aligner and of exposing a semiconductor wafer.

(32). A photomask data managing method comprising:

a step of obtaining data for a contact area with a photomask provided with a resist and a semiconductor manufacturing system or a photomask manufacturing system through an electrical communication line;

a step of storing the data in a database through a host computer; and

a step of managing the database through the host computer so that the database can be accessed from a plurality of user terminals connected to the host computer.

What is claimed is:

1. A photomask having a pattern formed with a resist on at least one face of a transparent plate, wherein the resist is not provided on the face at least at a contact point with a photomask manufacturing system.

2. A photomask having a pattern formed with a resist on at least one face of a transparent plate, wherein the resist is not provided on the face at least at a contact point with a photomask vessel or with a photomask jig.

3. A photomask having a pattern formed with a resist on at least one face of a transparent plate, wherein the resist is not provided on the face at least at a contact point with a pellicle frame.

4. The photomask according to claim 1, wherein the photomask manufacturing system comprises at least any one of a photomask exposure apparatus, a photomask-pattern writing apparatus, a resist application apparatus, a resist development apparatus, a photomask-dimension measurement apparatus, a photomask inspection apparatus, a photomask adjustment apparatus, and a photomask installation apparatus.

5. The photomask according to claim 1, wherein the photomask further has a pattern formed with a metal and a contact point with the photomask manufacturing system, the photomask vessel, the photomask jig, the pellicle frame, or the semiconductor manufacturing system is a pattern portion formed with the metal.

6. The photomask according to claim 1, wherein the photomask has a phase shifter on the face.

7. The photomask according to claim 1, wherein the transparent plate has an opening portion for shifting a phase to the face side.

8. The photomask according to claim 1, wherein the resist is a negative-type resist.

9. The photomask according to claim 1, wherein a conductive material is set between the resist and the transparent plate.

10. The photomask according to claim 1, wherein the resist is a chemical-amplification resist.

11. The photomask according to claim 1, wherein the resist contains at least any one of acrylic resin, novolac resin, phenol resin, black carbon, and metal oxide.

12. The photomask according to claim 1, wherein the resist is a resist used for darkening or shading of any one of at least g-beam, i-beam, ArF excimer laser beam, KrF excimer laser beam, and F₂ laser beam.

13. The photomask according to claim 1, wherein the transparent plate use a quartz substrate.
